(19) United States
(12) Patent Application Publication
(10) Pub. No.: US 2026/0036901 A1
(43) Pub. Date: Feb. 5, 2026

(54) ORGANOMETALLIC COMPOSITIONS WITH PHOSPHONATE ADDITIVES FOR EUV PATTERNING

(71) Applicant: Inpria Corporation, Corvallis, OR (US)

(72) Inventors: Matthew Voss, Corvallis, OR (US); Brian J. Cardineau, Corvallis, OR (US); Kai Jiang, Corvallis, OR (US); Fabian Felix Eberle, Corvallis, OR (US)

(21) Appl. No.: 19/284,303

(22) Filed: Jul. 29, 2025

Related U.S. Application Data
(60) Provisional application No. 63/678,642, filed on Aug. 2, 2024.

(51) Int. Cl. G03F 7/004

(52) U.S. Cl. CPC G03F 7/0042

(57) ABSTRACT

Organometallic precursor solutions containing one or more phosphonate, such as methylphosphonic acid, tert-butylphosphonic acid, diethoxyalyllphosphonate, benzylphosphonic acid, and phenylphosphonic acid, are described. Corresponding methods for forming radiation patternable coatings as well as methods for forming a pattern using a solventless developing process are also described. The incorporation of a phosphonate into an organometallic photoresist composition, such as an organotin photoresist composition, is described as a way to increase stability of organometallic precursor solutions, to improve the homogeneity of organometallic photoresist films, and/or to improve the patterning performance of organometallic photoresist coatings.

### CROSS REFERENCE TO RELATED APPLICATIONS

This application claims priority to copending U.S. provisional patent application 63/678,642 to Voss et al. filed Aug. 2, 2024, entitled “Organotin Phosphonate Compositions for EUV Patterning,” incorporated herein by reference.

### FIELD OF THE INVENTION

The invention related to organotin radiation sensitive patterning compositions and the use of additives to revise the patterning performance. The invention further related to precursor compositions with improved stability and methods of processing the precursor composition to perform the patterning, which is generally directed to ultrafine patterns such as in the production of semiconductor based devices.

### BACKGROUND

Semiconductor lithography is a complex and critical technology used to fabricate myriad and diverse devices that have dominated and transformed the modern world beginning in the 20th century. The semiconductor lithographic process is generally an iterative process involving repeated steps of deposition, patterning, and etching of many layers and materials to form the desired devices. As technology advances and new, increasing demands and requirements are placed upon each generation of devices, the need to develop processes and materials that are able to meet these requirements increases. One of the critical materials used in the semiconductor lithographic process is the photoresist in which an initial pattern is formed by exposure to radiation and is then subsequently transferred into the underlying substrate.

Organometallic photoresists have been shown to be promising materials for use in current and next-generation semiconductor lithography processing due to their ability to form high-resolution, high etch resistance, and high-fidelity patterns. These organometallic systems generally operate through radiation exposure-mediated formation of condensed oxide networks that drive contrast between irradiated (i.e., exposed) and non-irradiated (i.e., unexposed) regions of the material. A development process can then be used that can selectively remove the irradiated or the non-irradiated material to realize a physical pattern of material based on a latent image formed by the pattern of radiation. The specific composition of the patterning material can influence the patterning process, such as lithographic processing, and corresponding performance of metal oxide resist (MOR) materials, including the character of the resulting physical pattern.

### SUMMARY OF THE INVENTION

In a first aspect, the invention pertains to a precursor solution comprising a mixture of solvent, a radiation sensitive organometallic precursor composition with hydrolysable ligands, and a phosphonate, having a metal concentration from about 0.005 M to about 1.4 M. In some embodiments, the solution is essentially free of carboxylate functional groups, halogen groups, vinyl functional groups and phosphonate with C—OH groups.

In another aspect, the invention pertains to a method for the formation of a radiation patternable coating, the method comprising: depositing a precursor solution comprising a solvent and a precursor composition for forming a radiation sensitive film onto a surface of a substrate, wherein the precursor solution comprises a mixture of solvent, a radiation sensitive organometallic precursor composition with hydrolysable ligands, and a phosphonate; removing the solvent to form a solid coating comprising RM moieties and phosphonate moieties within an oxo-hydroxo network, wherein R is an organic ligand and M is a metal; irradiating the solid coating with patterned EUV radiation; performing a post exposure bake at a temperature of at least 205° C. for at least about 40 seconds; and after the post exposure bake, developing the solid coating to form a physical pattern.

In a further aspect, the invention pertains to a method for forming a pattern, the method comprising: developing a virtual image formed by irradiating a layer comprising radiation sensitive RSn moieties and phosphonate moieties in a solventless developing process, wherein developing comprises preferentially removing a non-irradiated portion of the virtual image to form a negative tone pattern.

In a further aspect, the invention pertains to a precursor solution comprising a mixture of solvent, a radiation sensitive organometallic precursor composition with hydrolysable ligands, and a phosphonate, having a tin concentration from about 0.005 M to about 1.4 M and a selected amount of water from about 150 ppm to about 5000 ppm, wherein the precursor solution has reduced dodecamer formation as measured by a lower optical density from about 210 nm to about 245 nm.

In a further aspect, the invention pertains to a precursor solution comprising a mixture of solvent, a radiation sensitive organometallic precursor composition with hydrolysable ligands, and a phosphonate, having a metal concentration from about 0.005 M to about 1.4 M, wherein the phosphonate comprises a diester compound represented by the formula R¹PO(OR²)₂, represented by Structure 1:

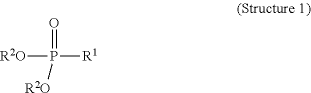

where R¹ is H or a linear, branched, cyclic, aromatic, substituted, or unsubstituted hydrocarbyl group having from 1 to 10 carbon atoms and each R² is independently chosen from a saturated, unsaturated, aromatic, or aliphatic hydrocarbyl group having from 1 to 10 carbon atoms.

### BRIEF DESCRIPTION OF THE DRAWINGS

FIG. 1 is a top-down view of negative-tone latent image based on aerial image.

FIG. 2A is a cartoon depicting the formation of T-topped cross sectional profiles of patterned features during development.

FIG. 2B is a cartoon depicting the formation of improved cross sectional profiles of patterned features formed from phosphonate enhanced photoresist compositions.

FIG. 3 is a set of cross-sectional transmission electron microscopy images collected for two unique phosphonate enhanced photoresist (PRX-P1 and PRX-P2) patterns in comparison to a non-phosphonate enhanced photoresist (PRX) pattern subjected to varying development durations.

FIG. 4A is a plot UV-Visible spectroscopy spectra for deposited coatings of organotin photoresist solution PRZ and phosphonate enhanced solution PRZ-P1 baked at 100° C. and 180° C.

FIG. 4B is a plot UV-Visible spectroscopy spectra for deposited coatings of organotin photoresist solution PRZ and phosphonate enhanced solution PRZ-P2 baked at 100° C. and 180° C.

FIG. 5 is a plot of integrated C-D stretch peak area as determined by FTIR over a range of EUV exposure doses for phosphonate enhanced photoresist coatings (R1 and R²) and non-phosphonate enhanced photoresist coatings (C1 and C2).

### DETAILED DESCRIPTION OF THE INVENTION

The addition of phosphonate compounds to organotin photoresist compositions can improve the patterning performance of the resist compositions. Phosphonate compounds can be added to the organotin photoresist precursor composition in solution and can coordinate, bind, chelate, and/or otherwise interact with the metal species in the photoresist composition. Such interactions between the phosphonate compounds and the metal species can stabilize the overall precursor composition against precipitation, frustrate the formation of high nuclearity (cluster size) species in solution that can affect film uniformity, and hinder undesired reactions with ambient environmental species. Applicant has made significant progress with respect to achieving consistent patterning using organotin patterning compositions based on hydrolysable ligands to form an oxo-hydroxo network with radiation sensitive Sn-C bonds. Selected additives can modify the nature of an amorphous network within the material. The compositions described herein leverage Applicant's prior extensive work on these patterning compositions and focus on the addition of phosphonate additives based on the potential ligand binding of the phosphonate functional group and changes in solubility associated with the phosphonate. The phosphonate compounds can improve the thermal stability of the tin-carbon bonds of both the exposed and unexposed photoresist and can enable wider processing conditions of the photoresist. In positive tone patterning, sufficient dealkylation should occur to render the irradiated regions soluble in corresponding positive tone developer solutions, but excessive dealkylation can produce insoluble tin oxide species in the irradiated regions. Correspondingly, in negative tone patterning, sufficient dealkylation should occur to render the irradiated regions insoluble or resistant to removal in negative tone development processes. Improved control over dealkylation can be useful for expanding and operating within the process window for either negative tone or positive tone patterning processes. Furthermore, the addition of phosphonate compounds to the organotin photoresist composition can improve the solubility of the photoresist films with respect to negative tone development and can lead to improved negative-tone patterning performance of the photoresist.

While the organotin photoresist compositions were designed to provide high patterning contrast upon irradiation, applicant has found that the inclusion of additives may be beneficial in precursor solutions to provide improved stability, in forming deposited films that can be more uniform, and in patterning with some adjustment of the radiolysis and radiation induced thermolysis that can improve reproducibility and decrease defects for patterning. The phosphonate additives described herein can improve precursor solution stability through the inhibition of tin clustering that can result in precipitation. Similarly, the additives can improve film uniformity resulting from coating of the precursor solution. The additive can also influence the radiolysis and radiation induced thermolysis efficiency to help achieve desirable patterning. As demonstrated herein, the use of phosphonate additives can reduce T-topping from development to have more vertical sidewalls in a developed pattern.

Applicant has also explored other desirable additives. The usefulness of additives to stabilize precursors solutions through inhibition of tin cluster formation is discussed generally in published U.S. patent application 2023/0143592 to Jiang et al. (hereinafter the '592 application), entitled “Stability-Enhanced Organotin Photoresist Compositions,” incorporated herein by reference. The '592 application discusses certain stabilizing compounds that can form ligands to the tin atom, which can be effective to slow hydrolysis. Applicant has also peroxide additives that can also form ligands to the tin. See, copending U.S. patent application Ser. No. 19/188,103 to Boutilier et al., entitled “Peroxide Stabilized Organotin Photoresist Compositions and Patterning,” incorporated herein by reference. The peroxide ligands may be radiation sensitive in the sense that irradiation of the deposited photoresist may cleave a peroxide ligand from binding to the tin atom. The present application extends stabilization to a new class of additive compositions that are shown to be effective to reduce T-topping and are likely non-volatile under general processing conditions.

A wide range of additives for organometallic photoresists is described in published U.S. patent application 2025/0138417 to Wang et al. (the '417 application), entitled “Additives for Metallic Photoresists,” incorporated herein by reference. The '417 application does not exemplify any additives and describes a very wide range of additives and metallic photoresists without any suggestions of what may be effective or why. The '417 application seems to be wild speculation of additives at unspecified concentrations that may help with increasing “hardness” of the resulting photoresist. The attachment of unsaturated functional groups, especially vinyl groups, onto carboxylic acid groups, sulfonic acid groups, or phosphonic acid groups, is described in published U.S. patent application 2025/0102907 to Lee et al. (hereinafter '907 application), entitled “Semiconductor Photoresist Composition and Method of Forming Patterns Using the Composition,” incorporated herein by reference. There is no explanation of the expected effect of the presence of the additives and the results in the Examples are difficult to interpret in view of the certain parameters not being clearly defined. Applicant has performed patterning using organotin composition in which the organic ligand bound to tin includes polyenes. See, copending U.S. patent application Ser. No. 19/059,783 to Jilek et al., entitled “Organometallic Compositions With Polyene Ligands, Radiation Sensitive Coatings With Bridging Organic Ligands And Patterning,” incorporated herein by reference. While with polyene ligands, evidence of bridging is seen, but no evidence of bridging is observed with vinyl groups in the ligands, see published U.S. patent application 2024/0100658 to Jelik et al., entitled “Direct Synthesis of Organotin Alkoxides,” incorporated herein by reference. The phosphonate additives described herein generally do not have vinyl or other unsaturated, non-aromatic, functional groups to avoid forming crosslinked additives, which may undesirably change the character of the patterned material.

Recently published patent applications suggest acids as additives include generally carboxylic acids, optionally in combination with organic substituted inorganic acids, for example, phosphonic acids or sulfonic acids. Asserted patterning improvement from inclusion of acidic additives, including phosphonic acid additives, is described in published U.S. patent application 2025/0216779 to Jang et al. (hereinafter '779 application), entitled “Semiconductor Photoresist Composition and Method of Forming Patterns Using the Composition,” incorporated herein by reference. The '779 application presents examples. The specific composition of the exemplified phosphonic acid additive has a carboxylic acid functional group attached. The '779 patent teaches the use of carboxylic acid additives, which can be directly provided in precursor solutions and/or attached as a functional group to a sulfonic acid compound or a phosphonic acid compound. The dominating feature of the '779 patent is the presence of carboxylic acid functionality, which may be combined with other functionalities.

Organotin compounds, in particular monoalkyltin compounds, have found use as high-performance photoresists for EUV lithography. The use of alkyl tin compounds in high performance radiation-based patterning compositions is described, for example, in U.S. Pat. No. 9,310,684 to Meyers et al., entitled “Organometallic Solution Based High Resolution Patterning Compositions,” incorporated herein by reference. Refinements of these organometallic compositions for patterning are described in U.S. Pat. No. 10,642,153 to Meyers et al., entitled “Organometallic Solution Based High Resolution Patterning Compositions and Corresponding Methods,” and 10,228,618 to Meyers et al. (hereinafter the '618 patent), entitled “Organotin Oxide Hydroxide Patterning Compositions, Precursors, and Patterning,” both of which are incorporated herein by reference.

Organotin photoresist precursor solutions can generally include one or more hydrolytically sensitive organotin compounds represented by the formula RSnL₃, where R is a linear, branched, (i.e., secondary or tertiary at the metal-bonded carbon atom), cyclic, aromatic, or olefinic organo group. As used in this art and herein, the expressions organo, hydrocarbyl and alkyl are used interchangeably unless indicated otherwise to refer to moieties capable of forming a functional group bound to tin at a carbon atom with various degrees of saturation, unsaturation and heteroatom introduction within the R group. In some cases, two or more distinct RSnL₃ compounds can be present together in a blend to form a photoresist precursor solution. Generally, each hydrocarbyl R group individually has from 1 to 31 carbon atoms with 3 to 31 carbon atoms for R groups having a secondary metal-bonded carbon atom and 4 to 31 carbon atoms for R groups with a tertiary metal-bonded carbon atom. For branched alkyl ligands, the compound can be represented by R¹R²R³CSnL₃, where R¹ and R² are independently an alkyl group with 1-10 carbon atoms, and R³ is hydrogen or an alkyl group with 1-10 carbon atoms. In some embodiments R¹ and R² can form a cyclic alkyl moiety, and R³ may also join the other groups in a cyclic moiety. Suitable branched alkyl ligands can be, for example, isopropyl (R¹ and R² are methyl and R³ is hydrogen), tert-butyl (R¹, R² and R³ are methyl), tert-amyl (R¹ and R² are methyl and R³ is —CHCH₃), sec-butyl (R¹ is methyl, R² is —CHCH₃, and R³ is hydrogen), cyclohexyl, cyclopentyl, cyclobutyl, and cyclopropyl. In some embodiments hydrocarbyl groups may include aryl, or alkenyl groups, for example benzyl, allyl, or alkynyl groups. In some embodiments the hydrocarbyl ligand R may include any group consisting solely of C and H, and containing 1-31 carbon atoms, for example: linear or branched alkyl (iPr, tBu, Me, nBu), cyclo-alkyl (cyclo-propyl, cyclo-butyl, cyclo-pentyl), olefinic (alkenyl, aryl, allylic), or alkynyl groups, or combinations thereof. In further embodiments suitable R groups may include R groups substituted with heteroatoms or functional groups including cyano, thio, silyl, ether, keto, ester, or halogenated groups (e.g., F, CF₃) or combinations thereof. Synthesis and usage of organotin photoresists with heteroatom functional groups have been described and exemplified, for example, in published U.S. Patent Application 2022/0064192 to Edson et al., entitled “Methods to produce organotin compositions with convenient ligand providing reactants”, U.S. Pat. No. 12,032,291 to Jilek et al., entitled “Organotin patterning materials with ligands having silicon/germanium; precursor compositions; and synthesis methods”, and published U.S. Patent Application 2023/0374388 to Jilek et al., entitled “Radiation sensitive organotin compositions having oxygen heteroatoms in hydrocarbyl ligand”, all of which are incorporated herein by reference.

The hydrolysable ligands L are generally Lewis bases that can react suitably with acidic protons of water or other Lewis acids, such as the tin atom, during hydrolysis, solvolysis or dissociative substitution by an additive of M-L bonds where M is a metal. Alternatively, these ligands may react with an appropriate reagent via oxidation or reduction reactions, in some embodiments, to form readily volatilized products. Ligands may generally be classified by the acid dissociation constant (pKa) of their conjugate acids, where desirable ligands for some embodiments have conjugate acid pKa values greater than about 4. Thus, L generally includes an atom binding to the metal, e.g., tin, that can undergo nucleophilic substitution involving H₂O and —OH. The resulting M—OH or M—OH₂ ligands may then react via subsequent condensation or dehydration steps to form a metal oxide-hydroxide network. The L ligands do not necessarily have to be the same as each other.

Suitable L ligands can include alkylamido or dialkylamido (—NR¹R², where R¹ and R² arc independently hydrocarbon groups with 1-10 carbon atoms or hydrogen), siloxo (—OSiR¹R²R³, where R¹, R², and R³ are independently hydrocarbon groups with 1-10 carbon atoms), silylamido (—N(SiR¹₃) (R²), where R¹ and R² are independently hydrocarbon groups with 1-10 carbon atoms), disilylamido (—N(SiR¹₃) (SiR²₃) where R¹ and R² are independently hydrocarbon groups with 1-10 carbon atoms), alkoxo and aryloxo (—OR, where R is an alkyl or aryl group with 1-15 carbon atoms), azido (—N₃), alkynido (—C═CR, where R is a hydrocarbon group with 1-9 carbon atoms), amidato (—NR¹ (COR2) where R¹ and R² are independently hydrocarbon groups with 1-7 carbon atoms or hydrogen), amidinato (—NR¹C (NR²) R³) where R¹R², and R³ are independently hydrocarbon groups with 1-8 carbon atoms or hydrogen), imido (—N(COR1) (COR2), where R¹ and R² are independently hydrocarbon groups with 1-8 carbon atoms or hydrogen), or fluorinated analogues thereof.

In some embodiments, the organotin photoresist composition can further include inorganic hydrolytically sensitive metal compounds represented by the formula MLₙ, where in general, M is a Group 2-Group 16 metal, and 2≤n≤6, and L is defined as above. Desirable metals for M can include Sn, Hf, Zr, W, Ta, Co, Ni, In, Sb, Bi, Te or others and desirable ligands for L can include alkoxides (—OR) and amides (—NR¹R²). Some representative MLₙ compounds include, for example, Sn(OtBu)₄, Sn(OtAm)₄, Sn(NMe₂)₄, Zr(OtBu)₄, Hf(NMe₂)+, In (OiPr)₃, and Sb(OEt)₃, which are available commercially from Sigma-Aldrich, Alfa Acsar, Gelest, Strem Chemical, and other suppliers.

In embodiments wherein the organotin photoresist solution comprises multiple metal-containing components, these mixtures can generally include at least about 0.5 mole percent of each metal component, in some embodiments at least about 5 mole percent and in further embodiments at least about 10 mole percent of each component. A person of ordinary skill in the art will recognize that additional ranges of mixture components within the explicit ranges above are contemplated and are within the present disclosure. It should be noted that purposely added metals are in contrast to metal contaminants that may persist in small amounts through purification processes or are inadvertently introduced during processing.

In some embodiments, the addition of phosphonate compounds into the organotin photoresist precursor composition can improve the solubility of the metal species within the photoresist precursor solution. Organotin compounds, such as organotin alkoxides and organotin amides, are generally hydrolytically sensitive and can react with water to form low solubility metal oxides and hydroxides in the form of clusters, particles, oligomers, and/or polymeric species that can form precipitates, although the organic ligands to the tin significantly help to resist condensation into clusters. In general, the formation of higher nuclearity tin species, such as dodecameric and other tin oxo clusters can be undesirable for solution stability and effective photoresist patterning. High nuclearity tin species can be prone to precipitation in precursor solutions and to forming inhomogeneity in the film which can give rise to insoluble tin-oxide species that can manifest as defects. While not wanting to be limited by theory, it is believed that the nuclearity of the tin species can be likened to pixels, such that a larger species embedding the amorphous network can limit the resolution at which patterned features can be produced without exceeding a specific defect threshold.

Generally, the abundance of dodecameric organotin cluster can be analyzed by any suitable method known in the art. In the precursor solutions as described herein, it is generally believed that dodecameric clusters are in equilibrium with clusters of different sizes and tin monomers. Evidence suggests that the additives change the equilibrium to reduce or substantially eliminate the dodecameric clusters in the precursor solutions and reducing the overall nuclearity in terms of average cluster size. As exemplified herein (see Example 1), Ultraviolet Visible Spectroscopy can be an effective method to analyze the abundance of dodecameric tin species in an organotin precursor solution or on a film deposited therefrom. The dodecamers can comprise RSn moieties and the identity of the organo ligand R can influence the absorbance properties of the dodecameric cluster. Applicant has experimentally determined that the dodecameric structures can have high optical densities at wavelength ranges from about 210 nm to about 245 nm. Notably, when R is tert-butyl the dodecameric clusters can have strong absorbance at 235 nm, as described in Haitjema ct al. in J. Photopolym. Sci. Technol., Vol. 30, No. 1, (2017), 99-102, incorporated herein by reference. Correspondingly, the absence of an absorption peak in this wavelength range suggests absence or low concentration of dodecamer clusters.

Dodecameric organotin oxo-hydroxo clusters as well as other clusters in equilibrium in the solution can exhibit wide disparities in solubility that vary with the identity of the R group, which can impact both the photoresist precursor solution and the films of the deposited photoresist. These lower solubility tin species can alter the character of the photoresist films due to potential introduction of non-uniformities and can lead to defects during processing and patterning of the photoresist, and it is therefore desirable to reduce their formation. With aging of the precursor solutions, the tin clusters can further agglomerate to form insoluble particulates that can settle from the solutions and shorten the shelf life of the precursor solutions. The presence of phosphonate compounds within the photoresist can reduce the formation of lower solubility tin species by chelating, coordinating, and/or otherwise interacting with tin species to inhibit or slow hydrolysis and with hydrolyzed tin species to enhance their solubility. The interaction between the phosphonate compounds and the organotin species can generally lead to inhibition of cluster formation and to the formation of lower nuclearity clusters and species in solution compared to organotin precursor solutions without phosphonate compounds, which can result in more stable precursor solutions and in a more homogeneous photoresist film. Phosphonate compounds can also coordinate and/or interact with the tin species in the photoresist to form species that are more resistant to hydrolysis and can mitigate the formation of insoluble hydrolysates and/or condensates. The phosphonate compounds can therefore improve the solubility of such species in an organic solvent to facilitate pattern development. Appropriate selection of a phosphonate additive to improve stability can be influenced by process parameters, additive identity, additive concentration, the identity of the organotin compounds, and water concentration in the precursor solution.

Cluster formation can be influenced by the contamination of the precursor solutions with water. It has been found that controlling the water level can result in consistent and stabler precursor solutions. Controlling water level would be similarly desirable in precursor solutions with stabilizing additives to also improve achievement of consistent patterning performance. In particular, the water level can be adjusted, generally by addition of small amounts of water to the solvent to achieve the target water levels, generally no more than about 10,000 ppm by weight in some embodiments, from about 150 ppm by weight to about 5,000 ppm by weight in some embodiments, and in additional embodiments from about 300 ppm by weight to about 2,500 ppm by weight. A person of ordinary skill in the art will recognize that additional ranges within the explicit ranges above are contemplated and are within the present disclosure. The use of water content adjustment is discussed further in U.S. Pat. No. 11,300,876 (herein the '876 patent) to Jiang et al., entitled “Stable Solutions of Monoalkyl Tin Alkoxides and Their Hydrolysis and Condensation Products,” incorporated herein by reference. The amount of water that can be effective to include in a precursor solution generally is dependent on the specific ligands of the precursor compounds and can be further influenced by the identity or concentration of a phosphonate additive. The addition of the phosphonates as described herein can help to mitigate an increase in precipitation from the water without sacrificing the consistency of the photoresist precursor solutions and resulting resist films while also improving the stability of the resist precursor solutions. To the extent that precursor solutions can maintain or improve stability with higher water concentrations, improved consistency and wafer to wafer reproducibility can be realized. Precursor solution formulations with an elevated baseline water concentration can mitigate the relative percent change in water concentration from ambient moisture uptake. The percent change is believed to be directly related to fluctuations in patterning results such that a lower change in the percentage can mitigate the magnitude of the fluctuations and improve wafer to wafer reproducibility.

In some embodiments, it can be desirable to adjust the water level to a relatively high level to improve the solubility of organotin phosphonate structures that form as a result of hydrolysis and/or condensation mechanisms. With certain organotin precursors or combinations of organotin precursors, the addition of a phosphonate compound can enable the stability of organotin precursor solutions with relatively high water levels that can otherwise precipitate and become unstable faster without a phosphonate compound. As used herein, relatively high water levels can be from about 800 ppm to about 20,000 ppm in some embodiments, from about 1,500 ppm to about 10,000 ppm in other embodiments, and from about 2,000 ppm to about 5,000 ppm in further embodiments. While not wanting to be limited by theory, it is believed that higher water concentrations can promote the formation of more soluble organotin phosphonate structures. The desired water concentration to increase the solubility of mixtures of phosphonates and organotin species in a solvent or a system comprising a solvent and water can vary with the identity of the phosphonate compound or the organotin compound. The water concentration of the precursor solution can be selected accordingly. In some embodiments, the phosphonate enhanced organotin precursor solution can precipitate at lower water concentrations over time, generally under 500 to 800 ppm, but produce solutions with no visible precipitate over time at higher water concentrations. Sec Example 4 below. Selection of an appropriate water concentration for improved stability can be dependent on the concentration or identity of the phosphonate additive and the identity of the organotin compound, and these determinations can be readily determined by a person of ordinary skill in the art using the teachings herein. In general, the addition of a phosphonate compound to an organotin photoresist precursor solution can reduce the reliance on limiting and/or controlling the water concentration to realize consistent solubility of organotin structures in precursor solutions. This can improve reproducibility of patterning performance, as the phosphonate enhanced formulations are more resistant to precipitation at certain water concentrations. A person of ordinary skill in the art will recognize that additional ranges of higher water levels within the explicit ranges above are contemplated and are within the present disclosure.

The lower molecular weight and hydrolytically robust species provided by the inclusion of phosphonate compounds in the organotin photoresist composition can also result in high fidelity patterns with low roughness (e.g., line-width roughness, LWR). During deposition, for example during a spin-coating process, the smaller clusters and species afforded by the phosphonate-stabilized organotin species relative to non-phosphonate stabilized compositions can result in more soluble, lower molecular weight species in the deposited film. After patterning the film with radiation, such as with extreme ultraviolet (EUV) photons, the smaller and lower molecular weight species straddling the edge of the features provide more fine control over the formation of the features after development. It is observed that the inclusion of the phosphonate additive reduces T-topping observed in the physically patterned structure as described further below.

The lower molecular weight species can be advantageous for improving the quality of patterned features, especially as developed using dry development approaches, for example etching, plasma development, gaseous developers, or the like. While not wanting to be limited by theory, it is believed that efficacy of dry development techniques may be limited by the developer species' ability to access and interact with organotin species in the film. The ability to access and interact with organotin species can be influenced by the physical morphology of the film, such that certain properties may improve development quality by appropriate metrics, for example uniformity, critical dimension consistency, and line edge roughness (LER). The speciation of organotin structures can influence the porosity of the film, and more porous films that maintain chemical contrast can be more penetrable by developer species which can enhance development quality. Smaller organotin structures can reduce steric hindrance that can otherwise prevent developer species from accessing and interacting with certain areas of the organotin structures during the development process.

As described herein, the phosphonate compounds can coordinate with the metal species in the photoresist and can modulate the hydrolysis/condensation processes and pathways that occur during the deposition process. As hydrolysis/condensation proceeds during deposition, the phosphonate compounds can become incorporated into the metal oxide hydroxide network through formation of Sn—O—P and/or Sn—O—P—O—Sn bonds which, owing to the presence of the organophosphorus constituents, can lead to more soluble as-deposited photoresist films. Furthermore, the formation of discrete organotin oxo clusters during hydrolysis/condensation of the tin species during deposition, which can phase segregate and lead to defects, can be mitigated by the presence of the phosphonate compounds that can interfere with the hydrolysis/condensation pathways that lead to the formation of such oxo clusters. After exposure to radiation, the irradiated (exposed) areas can condense to form an insoluble metal oxide hydroxide network incorporating phosphorous species that can exhibit much decreased solubility compared to the non-irradiated (unexposed) areas.

The presence of phosphonate compounds in organotin photoresist compositions can reduce the post-irradiation thermolytic cleavage of Sn—C bonds that may have survived irradiation. While not wanting to be limited by theory, it is believed that exposure of monoalkyl tin species to radiation can lead to cleavage of the Sn—C bonds in a radiolysis process. After initial radiation exposure and radiolysis of at least some Sn—C bonds, subsequent thermal processing, such as during a post-exposure bake (PEB), can lead to additional Sn—C bond cleavage via thermolysis in the irradiated regions in a process known as radiation-induced thermolysis (RIT). Therefore, there occurs an additional significant loss of Sn—C bonds within the irradiated regions of the photoresist film during the post-exposure bake process. By including phosphonate compounds in the organotin photoresist compositions, the RIT process can be hindered and the loss of additional Sn—C bonds during post-exposure heating processing can be reduced. The presence of phosphonates can thus enable processing of the photoresist compositions at higher temperatures, such as during a PEB process. Higher PEB temperatures can be useful to drive further densification of the exposed material and can lead to a reduction in dose needed to achieve the desired critical dimension (CD) of patterned features. As a result of higher processing temperatures, higher densities of the exposed regions can be achieved which can increase the etch resistance of the patterned material. Generally, higher processing temperatures can be used for dry development techniques than wet development techniques and the addition of phosphonate compounds can enable desired combinations of high temperature processing and dry development. While not wanting to be limited by theory, high temperatures can be desirable to provide sufficient densification of the material to render the irradiated regions resistant to removal by dry developer compositions. Conversely, wet development can be more solubility driven and excessively high temperatures can result in the thermal dissociation and decomposition of organo ligands in both the irradiated and non-irradiated regions which can neutralize contrast.

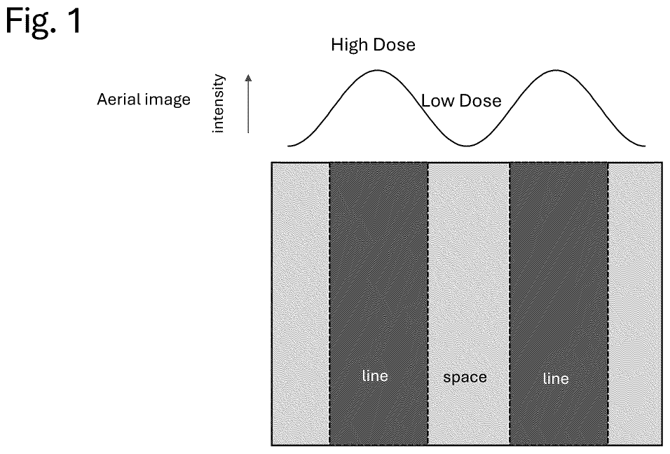

While not wanting to be limited by theory, it is believed that the magnitude of the RIT effect (i.e., the amount of Sn—C bond cleavage that occurs during post-exposure heating) is correlated with the polarity of the film wherein high film polarity leads to increased radiation-induced thermolysis. In other words, Sn—C bonds in environments with higher polarizability are more easily cleaved than the Sn—C bonds in lower polarity environments. Owing to the organic ligand(s) of the phosphonate compounds within the organotin resist matrix, the polarizability of the resist film can be decreased which can be useful for reducing the amount of Sn—C cleavage during the PEB process. Applicant has also observed that the introduction of fluoride ions into the matrix film also lowers the dose for C—Sn bond cleavage, which is consistent with polar bonds in the matrix increasing RIT. See published U.S. patent application 2025/005627 to Cardineau et al., entitled “Organotin Photoresist Compositions Having Fluoride Generator Compounds, Fluorinated Organotin Coatings and Patterning,” incorporated herein by reference. The Sn—C concentration generally correlates to the dose delivered to the material, which can depend on the position within the aerial image of radiation delivered to the film. For example, for an aerial image of lines projected onto the photoresist surface, the intensity of light generally follows a sinusoidal distribution across the surface. FIG. 1 illustrates the relationship between the aerial image and the resulting (negative-tone) latent image of lines and spaces in the film. As shown in FIG. 1, the areas corresponding to high light intensity (i.e., high dose) of the aerial image result in lines and the areas corresponding to low light intensity correspond to spaces. As discussed herein, absorption of radiation by the photoresist leads to cleavage of Sn—C bonds. The intensity of the radiation within the aerial image varies with the location across the aerial image such that the intensity of radiation (i.e., dose) decreases from the center of the line feature to the center of the space feature. Therefore, the amount of Sn—C bond cleavage varies accordingly across the aerial image.

When developing the latent image on an organometallic photoresist coating, a developer can be selected to remove the irradiated regions in a positive tone process or to remove the non-irradiated regions in a negative tone process. Following negative tone development, features such as line space patterns or even pillars can have non-uniform cross sectional profiles. The removal of excess material during development processes can result in cross sectional profiles having a tapered feature width wherein the critical dimension of the patterned feature decreases from the top of the organometallic photoresist coating to the substrate supporting the organometallic coating. These tapered profiles are often referred to as ‘T-topping’ in the art.

As exemplified herein and has been previously observed, T-topping can result from the patterning process. While there may be various mechanisms that can result in T-topping, during the processing of irradiated films leading to development, the supply of water to drive the network adjustment diffuses from the surface so if diffusion becomes rate-limiting, this can result in T-topping due to the top of the irradiated resist reacting with absorbed H₂O before the molecules can diffuse to the bottom of the film. For high flow environments where water can be continually replaced at the surface of the wafer, hydrolysis/condensation reactions can continue to occur near the surface of the resist at a higher rate than the bottom of the resist due to the limited ability of water and/or O-containing species to diffuse before reacting. Thus, it can be inefficient to attempt to compensate for the T-topping through adjustment of a single PEB process condition. Attempts to compensate for T-topping through more elaborate post exposure processing is described in copending U.S. patent application Ser. No. 19/065,726 to De Schepper et al., entitled “Controlled Environment Processing, Rest Steps, and Baking Processes for Metal Oxide-Based Resist Patterning,” incorporated herein by reference.

The tapered profiles can be undesirable and can produce poor critical dimension uniformity, pattern collapse, and poor etch transfer of the pattern into the substrate, In some embodiments, ideal patterned features have a vertical side profile and form an approximate 90 degree angle with the substrate. The cross-sectional profiles of the patterned features can be analyzed through a variety of techniques, for example cross sectional transmission electron microscopy (XTEM). Generally, improvements to cross sectional profiles, with closer to a vertical side profile, can be observed through the visual inspection of the microscopy images.

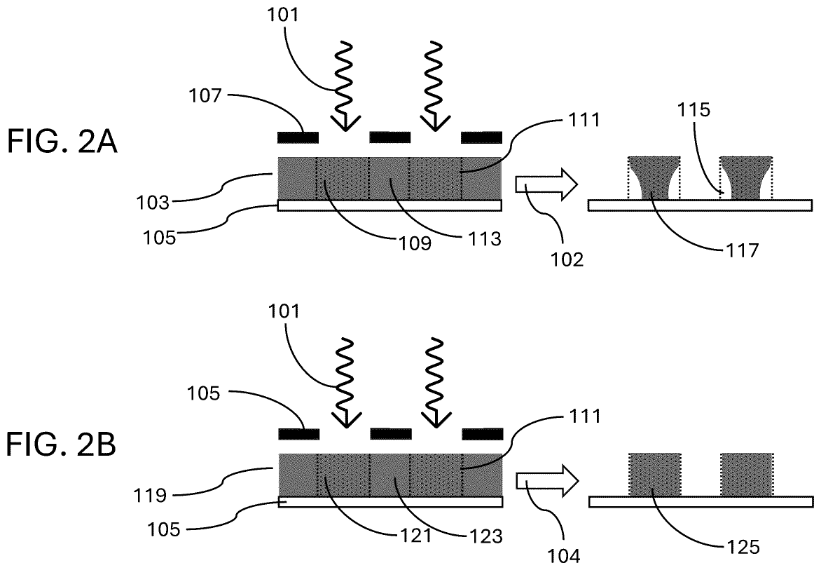

FIG. 2A depicts the T-topping of patterned organometallic features. Radiation source 101 is directed on to organometallic photoresist coating 103 supported by substrate 105 through photomask 107 to form irradiated regions 109 within irradiation boundaries 111 and non-irradiated regions 113. In development step 102, non-irradiated regions are selectively removed and some exposed regions within the irradiation boundaries 115 are inadvertently removed to form T-topped features 117.

The addition of phosphonate compounds to organotin photoresist precursor solutions can reduce the severity of T-topping and produce more vertical cross sectional profiles. The reduction in T-topping of patterned features is exemplified with dry development techniques, although similar improvements may be observed under certain wet development conditions, depending on materials and process parameters. As exemplified herein, the addition of phosphonates to an organotin photoresist precursor solution can produce cross sectional transmission electron microscopy (XTEM) images of line space patterns having reduced T-topping of features developed with dry development techniques. FIG. 2B depicts the reduction in T-topping resulting from the addition of a phosphonate to an organometallic photoresist precursor solution. Radiation source 101 is directed on to phosphonate enhanced organometallic photoresist coating 119 supported by substrate 105 through photomask 107 to form irradiated regions 121 within irradiation boundaries 111 and non-irradiated regions 123. In development step 104, non-irradiated regions are selectively removed to form patterned features 125 having an improved cross sectional profile.

In some embodiments, T-topping of cross sectional profiles can arise from a top region of the film with high developer resistance in comparison to the middle or lower regions having a lower resistance to the developer species. The middle of lower regions can be excessively removed by the developer species, while the top layer is not, resulting in a cross sectional profile having a wider top layer. While not wanting to be limited by theory, higher developer resistance of the top layer can be a result of EUV photon attenuation or interactions between the top layer and ambient species, for example H₂O, CO₂, O₂, or NOx. The phosphonate enhanced coatings can contribute to a more uniform interaction between the coating and developer across the vertical height of the feature. The phosphonate compounds can interact with the chemical environment of the photosensitive coating to normalize developer resistance profiles and produce more uniform profiles with regard to variations in critical dimension across the vertical height of the feature. While not wanting to be bound by theory, the interactions can involve polarity, steric hindrance, or cross linking which are believed to influence the mechanisms of dry development techniques.

The phosphonate additive compounds are generally compounds having a P—C bond and are represented by the formula RIPO(OR²)₂, represented by structure 1:

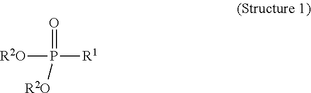

where R¹ is H or a linear, branched, cyclic, aromatic, substituted, or unsubstituted hydrocarbyl group having from 1 to 10 carbon atoms and each R² is independently chosen from H or a saturated, unsaturated, aromatic, or aliphatic hydrocarbyl group having from 1 to 10 carbon atoms. If R¹ and both R² are H, the compound is phosphorous acid, which lacks organic moieties. The phosphonate compounds can be protonated (R²═H) and can therefore be alternatively referred to as phosphonic acid compounds. For embodiments with R²═H, the degree of protonation can depend on the basicity of other species around, and the properties of solutions can be referenced relative to the overall composition and not necessarily referencing the overall degree of protonation. In embodiments where one R² is not H, the compound can be referred to as a mono phosphonic acid ester or a phosphonate and these compounds can have improved stability in certain organotin precursor solution formulations in comparison to embodiments where R² is H. In some embodiments where R² are both not H, the compound can be referred to as a phosphonic acid diester or a phosphonate diester, although the compounds can still be referred to as phosphonates, an umbrella term which encompasses both monoesters and diesters of phosphonic acids. Phosphonic acid diesters can similarly have improved stability with regard to precipitation in comparison to embodiments where R² are both H. For the purpose of this disclosure, the term phosphonate is understood to encompass phosphonates, phosphonic acids, phosphonic acid esters, and any other compounds falling within the scope of Structure 1, unless explicitly indicated otherwise. In some embodiments, the phosphonate compounds can include methylphosphonic acid, tert-butylphosphonic acid, diethoxyalyllphosphonate, and allylphosphonic acid represented by the following structures

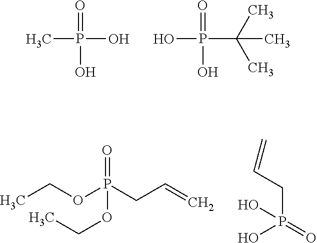

In some embodiments, the phosphonate compound can include aromatic groups, such as benzylphosphonic acid and phenylphosphonic acid. In some embodiments, the phosphonate compound can include unsaturated alkyl groups such as a cyclopentyldienyl group. In some embodiments, the phosphonate compound can include conjugated alkenes such as cyclohepta-2,4,6-triene, although some embodiments of particular interest exclude alkene groups from the phosphonate. Similarly, other embodiments of particular interest also exclude carboxylate functional groups, hydroxyl functional groups, halogen functional groups, or other heteroatom functional groups. In some embodiments, the phosphonate compounds have R¹ as a saturated alkyl group or in some other embodiments as an aromatic group, which may involve heteroatoms. The selection of the organic ligands of the phosphonate can depend on other parameters of the precursor solution. In general, the patterning compositions described herein leverage the desirable patterning properties of the organotin compounds and the additives are relied upon for potential ligand formation with the tin atoms to moderate hydrolysis while also modifying the solubility properties. In some embodiments, functional groups on the phosphonates may be appropriate, and the specific focus can be elucidated in the claims.

In some embodiments, the phosphonate compound can include a secondary or tertiary carbon bonded to the P atom. Some suitable examples of phosphonate compounds having a secondary or tertiary carbon bonded to the P atom include the structures:

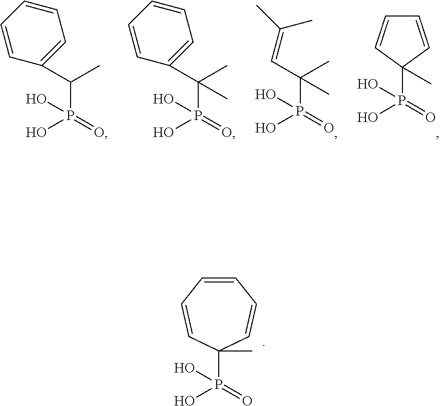

In some embodiments, R¹ can be substituted with heteroatom such as N, S, O, or F at any position on R¹ as long as there is an α-carbon bonded directly to the phosphorus atom (e.g., R¹ forms a P—C bond). In some embodiments, the phosphonate compound can include a nitro group (—NO₂), such as represented by the following structure:

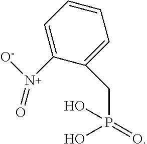

Recent work has examined the use of functionalized phosphonates as additives for organometallic photoresists, generally also combined with a carboxylic acid and/or a sulfonic acid. See for example, published U.S. patent application 2025/0216779 to Jang et al. (hereinafter the '779 application), entitled “Semiconductor Photoresist Composition and Methods of Forming Patterns Using the Composition,” incorporated herein by reference. In the '779 application, the compositions include a carboxylic acid additive, although it has comparative examples without the carboxylic acid. In addition, the phosphonate additive exemplified in the '779 application is functionalized with a carboxylate group, P1=3-phosphonopropionic acid (HO₂CCH₂CH₂PO(OH)₂), which is in addition to the generally added separate carboxylate group. While the inventive embodiments in the '779 application all include carboxylic acid and the preferred embodiments include modified phosphonates, the broader disclosure is somewhat obscure with respect to the scope of phosphonates, and no specific formulas are presented for unmodified phosphonates. Additives with phosphonic acid groups are also discussed in published U.S. patent application 2025/0102907 to Lee et al. (alkene compound with phosphonic acid group), entitled “Semiconductor Photoresist Composition and Methods of Forming Patterns Using the Composition,” and a range of potential additives including phosphonic acids are mentioned in published U.S. patent application 2025/0138417 to Wang et al., entitled “Additives for Metallic Photoresist,” both of which are incorporated herein by reference.

The phosphonate compounds can be introduced into the metal oxide photoresist composition through any suitable means. The phosphonate compounds are generally solids and can be introduced as powders. For these embodiments, solvent selection can be influenced by solubility of the phosphonate compound, which are generally soluble in alcohols. In some embodiments, the phosphonate compounds can be introduced by dissolving appropriate amounts of the compounds into the solvent composition before or after addition of the metal resist precursors and/or other ingredients. In some embodiments, the phosphonate compounds can be mixed with the metal resist precursors prior to introduction of a solvent. The phosphonate compound is generally soluble in the precursor solution, but it may not necessarily be soluble in an intermediate blend. Regardless, it can be useful to describe suitable amounts of phosphonate compounds by mole percents relative to the total metal, e.g., mol. percent=(mol. phosphonate/mol. metal)*100. In some embodiments, the phosphonate compounds can be present in the resist composition at about from 0.1 mole percent relative to the total metal to about 250 mole percent relative to the total metal, from about 0.5 mole percent to about 100 mole percent in further embodiments, from about 0.5 mole percent relative to the total metal to about 50 mole percent relative to the total metal in some embodiments, and from about 1 mole percent relative to the total metal to about 25 mole percent relative to the total metal in other embodiments. In embodiments where the organometallic photoresist composition does not contain a non-tin metal, the phosphonate concentration can be expressed as a mole percent relative to the concentration of Sn and the same ranges of relative concentrations can be useful. In some embodiments, the precursor solution can comprise more than one distinct phosphonate compound. If more than one phosphonate compound is present, the total amounts of all phosphonate compounds can also fall within the above ranges. A person of ordinary skill in the art will recognize that additional ranges of phosphonate relative concentrations within the explicit ranges above are contemplated and are within the present disclosure.

Suitable concentrations of tin in the photoresist composition can be conveniently specified based on tin ion molar concentration. In general, the photoresist solutions can include from about 0.005 M to about 1.4 M tin cation, in further embodiments from about 0.02 M to about 1.2 M, and in additional embodiments from about 0.1 M to about 1.0 M tin cation. In embodiments wherein non-Sn metals are added to the photoresist solution, the concentrations of any other metals can be correspondingly specified through the molar fraction values for the metals relative to tin. Total non-tin metal in the precursor solution generally can range from about 0.025 mole % to about 10 mole % of the total metal ions and in further embodiments from about 10 mole % to about 50 mole % of the total metal ions. A person of ordinary skill in the art will recognize that additional ranges of tin cations within the explicit ranges above are contemplated and are within the present disclosure.

In general, the desired various compounds (e.g., organotin compounds, phosphonate compounds, hydrolysable metal compounds, etc.) can be dissolved in an organic solvent, e.g., alcohols, aromatic and aliphatic hydrocarbons, esters or combinations thereof. In particular, suitable solvents include, for example, aromatic compounds (e.g., xylenes, toluene), ethers (anisole, tetrahydrofuran), esters (propylene glycol monomethyl ether acetate, ethyl acetate, ethyl lactate), alcohols (e.g., 4-methyl-2-pentanol, 1-butanol, methanol, isopropyl alcohol, 1-propanol, 1-pentanol), ketones (e.g., methyl ethyl ketone), mixtures thereof, and the like. In general, organic solvent selection can be influenced by solubility parameters, volatility, flammability, toxicity, viscosity and potential chemical interactions with other processing materials. After the components of the solution are dissolved and combined, the character of the species may change as a result of partial in-situ hydrolysis, hydration, complexation and/or condensation. When the composition of the solution is referenced herein, the reference is to the components as added to the solution as ingredients, since complex formulations may undergo solvolysis and ligand metathesis, or produce metal polynuclear species in solution that may not be well characterized. Similarly, pH dependent groups have a degree of protonation based on the particular constituents and solvent and terminology is not based on degree of protonation unless specifically indicated otherwise. For certain applications it is desirable for the organic solvent to have a flash point of no less than about 10° C., in further embodiments no less than about 20° C. and in further embodiment no less than about 25° C. and a vapor pressure at 20° C. of no more than about 10 kPa, in some embodiments no more than about 8 kPa and in further embodiments no more than about 6 kPa. A person of ordinary skill in the art will recognize that additional ranges of flash point and vapor pressure within the explicit ranges above are contemplated and are within the present disclosure.

The photoresist solutions with organotin compositions and phosphonate compounds can be used to form radiation-patternable phosphonate-enhanced organotin oxo hydroxo films, and such coatings can be formed using any suitable method known in the art. Spin coating can be particularly desirable for forming coatings using the photoresist solutions. In a typical spin coating process, a volume of a photoresist solution is introduced onto the surface of a substrate, and the substrate is rotated at high speeds to drive rapid evaporation and hydrolysis processes to enable the formation of a radiation patternable coating. In some embodiments, the substrate can be spun at rates (i.e., spin speeds) from about 500 rpm to about 10,000 rpm, in further embodiments from about 1,000 rpm to about 7,500 rpm, and in additional embodiments from about 2,000 rpm to about 6,000 rpm. The spin speed can be adjusted to obtain a desired coating thickness and can generally depend on the dimensions of the substrate used. The spin coating can be performed from about 5 seconds to about 5 minutes and in further embodiments from about 15 seconds to about 2 minutes. An initial low speed spin, e.g., at 50 rpm to 250 rpm, can be used to perform an initial bulk spreading of the composition across the substrate. A back side rinse, edge bead removal step, or the like can be performed with water or other suitable solvent to remove any edge bead. A person or ordinary skill in the art will recognize that additional ranges of spin coating parameters within the explicit ranges above are contemplated and are within the present disclosure.

A substrate generally presents a surface onto which the coating material can be deposited, and the substrate may comprise a plurality of layers in which the surface relates to an upper most layer. The substrate surface can be treated to prepare the surface for adhesion of the coating material. Prior to preparation of the surface, the surface can be cleaned and/or smoothed as appropriate. Suitable substrate surfaces can comprise any reasonable material. Some substrates of interest include, for example, silicon wafers, silica substrates, other inorganic materials, polymer substrates, such as organic polymers, composites thereof and combinations thereof across a surface and/or in layers of the substrate. In some embodiments, the substrate can comprise a patterned structure such as described by Stowers et al. in U.S. Pat. No. 10,649,328, entitled “Pre-Patterned Lithography Templates, Process Based on Radiation Patterning Using The Templates And Processes To Form The Templates”, incorporated herein by reference.

The thickness of the coating generally can be a function of the precursor solution concentration, viscosity and the spin speed for spin coating. For other coating processes, the thickness can generally also be adjusted through the selection of the coating parameters. In some embodiments, it can be desirable to use a thin coating to facilitate formation of small and highly resolved features in the subsequent patterning process. For example, the coating materials after drying can have an average thickness of no more than about 250 nanometers (nm), in additional embodiments from about 1 nm to about 50 nm, in other embodiments from about 2 nm to about 40 nm and in further embodiments from about 3 nm to about 25 nm. A person of ordinary skill in the art will recognize that additional ranges of thicknesses within the explicit ranges above are contemplated and are within the present disclosure. The thickness can be evaluated using non-contact methods of x-ray reflectivity and/or ellipsometry based on the optical properties of the film. In general, the coatings are relatively uniform to facilitate processing. In some embodiments, such as high uniformity coatings on reasonably sized substrates, the evaluation of coating uniformity or flatness may be evaluated with, for example, a 1 centimeter edge exclusion, i.e., the coating uniformity is not evaluated for portions of the coating within 1 centimeter of the edge, although other suitable edge exclusions can be selected.

While heating may not be needed for successful application of the deposition process, it can be desirable to heat the coated substrate to densify the coating material, to speed the processing, to increase the reproducibility of the process, and/or to facilitate vaporization of the hydrolysis by-products, such as alcohols and/or amines. In embodiments in which heating of the coated substrate is performed prior to irradiation, the coated substrate can be heated to temperatures from about 45° C. to about 250° C., in further embodiments from about 50° C. to about 225° C. and in additional embodiments from about 55° C. to about 225° C. The heating can generally be performed for at least about 0.1 minute, in further embodiments for about 0.25 minutes to about 30 minutes, in other embodiments from about 0.5 minutes to about 15 minutes, and in additional embodiments from about 0.75 minutes to about 10 minutes. A person of ordinary skill in the art will recognize that additional ranges of heating temperatures and times within the explicit ranges above are contemplated and are within the present disclosure.

Generally, photoresist coatings can be patterned using radiation. Suitable radiation sources include extreme ultraviolet (EUV), ultraviolet (UV), or electron beam (EB) radiation. For fabrication of semiconductor devices, EUV radiation can be desirable due to its higher resolution compared to UV radiation, and its higher throughput compared to electron beam (EB)-based processing. Radiation can generally be directed to the substrate material through a reticle, or a radiation beam can be controllably scanned across the substrate to form a latent image within the resist coating.

As have been employed for photolithography in the semiconductor industry, some suitable sources of radiation can include wavelengths of 248 nm, 193 nm, or about 13.5 nm. A krypton fluoride (KrF) laser can be used as a source for 248 nm ultraviolet light, and an argon fluoride (ArF) laser can be used as a radiation source for 193 nm ultraviolet light. EUV light has been used for lithography at 13.5 nm which is generally generated from a Xe or Sn plasma source, and such sources are commercially available as EUV exposure tools fabricated by ASML Holding N.V. Netherlands.

The amount of electromagnetic radiation can be characterized by a fluence or dose which is obtained by the integrated radiative flux over the exposure time. For embodiments in which EUV radiation is used, suitable radiation doses can be from about 1 mJ/cm² to about 150 mJ/cm², in further embodiments from about 2 mJ/cm² to about 100 mJ/cm² and in further embodiments from about 3 mJ/cm² to about 50 mJ/cm². A person of ordinary skill in the art will recognize that additional ranges of radiation fluences within the explicit ranges above are contemplated and are within the present disclosure.

Following exposure to radiation and the formation of a latent image, a subsequent post-exposure bake (PEB) is typically performed. In some embodiments, the PEB can be performed at temperatures from about 45° C. to about 275° C., in additional embodiments from about 50° C. to about 250° C., in other embodiments from about 90° C. to about 225° C., and in further embodiments from about 100° C. to about 205° C. In other embodiments, the PEB can be performed at temperatures at least about 205° C. and in further embodiments from about 205° C. to about 275° C. The post exposure heating can generally be performed for at least about 0.1 minute, in further embodiments from about 0.5 minutes to about 30 minutes and in additional embodiments from about 0.75 minutes to about 10 minutes. A person of ordinary skill in the art will recognize that additional ranges of PEB temperatures and times within the explicit ranges above are contemplated and are within the present disclosure. The PEB can be designed to further consolidate the exposed regions without decomposing the un-exposed regions into a metal oxide. The thermal stabilization of the C-Sn bond due to the phosphonates can allow for heating to higher temperatures with less decomposing of C-Sn bonds in the non-exposed regions.

Following performing a PEB, development of the image involves the contact of the patterned coating material including the latent image to a developer composition to remove either the un-irradiated coating material to form the negative image or the irradiated coating to form the positive image. For wet development techniques wherein the patterned coating material is contacted with a developer solution composition, irradiated regions of organotin oxide hydroxide coatings are generally hydrophilic and are thus soluble in aqueous bases and insoluble in organic solvents; conversely, non-irradiated regions are generally hydrophobic and are thus soluble in organic solvents and insoluble in aqueous bases. For negative tone imaging with wet development techniques, the developer can be an organic solvent, such as the solvents used to form the precursor solutions. In some embodiments, the developer composition is a reactive gas or a plasma and the irradiated regions of organotin oxide hydroxide coatings are generally more resistant to removal by the developer species, which may be due to the higher reactivity of the organic moieties present in higher concentrations in non-irradiated section of the film, although not wanting to be limited by theory. The developer composition can be applied to the organotin coating to form a negative tone pattern by preferentially removing the non-irradiated regions.

The addition of phosphonate compounds to the organotin photoresist composition can significantly influence the solubility properties of the exposed and unexposed regions of the film. Some phosphonate compounds having bulky organic groups can enable positive tone imaging. In some embodiments, suitable developers can be aqueous bases. To reduce contamination from the developer, it can be desirable to use a developer that does not have metal atoms. Thus, quaternary ammonium hydroxide compositions, such as tctracthylammonium hydroxide, tetrapropylammonium hydroxide, tetrabutylammonium hydroxide or combinations thereof, are desirable positive tone developers. In general, the quaternary ammonium hydroxides of particular interest can be represented with the formula RANOH, where R=a methyl group, an ethyl group, a propyl group, a butyl group, or combinations thereof. The coating materials described herein generally can be developed with the same developer commonly used presently for polymer resists, specifically tetramethyl ammonium hydroxide (TMAH). Commercial TMAH is available at 2.38 weight percent. Furthermore, mixed quaternary tetraalkyl-ammonium hydroxides can be used. In general, the developer can comprise from about 0.5 to about 30 weight percent, in further embodiments from about 1 to about 25 weight percent and in other embodiments from about 1.25 to about 20 weight percent tetra-alkylammonium hydroxide or similar quaternary ammonium hydroxides. A person of ordinary skill in the art will recognize that additional ranges of developer concentrations within the explicit ranges above are contemplated and are within the present disclosure. For a positive tone developer, it can be desirable to dissolve material densified from a relatively high radiation dose, assuming that the non-irradiated material is not significantly removed.

For the negative tone imaging with a wet developer composition, the developer can be an organic solvent, such as the solvents used to form the precursor solutions. In general, developer selection can be influenced by solubility parameters with respect to the coating material, both irradiated and non-irradiated, as well as developer volatility, flammability, toxicity, viscosity and potential chemical interactions with other process material. In particular, suitable developers include, for example, aromatic compounds (e.g., benzene, xylenes, toluene), esters (e.g., propylene glycol monomethyl ester acetate (PGMEA), ethyl acetate, ethyl lactate, n-butyl acetate, butyrolactone), alcohols (e.g., 4-methyl-2-pentanol, 1-butanol, isopropanol, 1-propanol, methanol), ketones (e.g., methyl ethyl ketone, acetone, cyclohexanone, 2-heptanone, 2-octanone), ethers (e.g., tetrahydrofuran, dioxane, anisole) and the like. Improved developer compositions have been described in published U.S. Patent Application No.: 2020/0326627 to Jiang et al., entitled “Organometallic Photoresist Developer Compositions and Processing Methods,” incorporated herein by reference. Improved developer solutions generally comprise a reference organic solvent composition and an additive composition having a higher polarity and/or hydrogen-bonding character than the reference solvent composition. In one example, an improved developer composition can comprise PGMEA and acetic acid. The development can be performed for about 5 seconds to about 30 minutes, in further embodiments from about 8 seconds to about 15 minutes and in addition embodiments from about 10 seconds to about 10 minutes. A person of ordinary skill in the art will recognize that additional ranges within the explicit ranges above are contemplated and are within the present disclosure.

For negative tone development, developer selection can be effectively influenced by solubility parameters with respect to the coating material, both irradiated and non-irradiated, as well as developer volatility, flammability, toxicity, viscosity and potential chemical interactions with other process material. Some useful developer compositions for these organotin oxide photoresists have been described in published U.S. Patent Application No. 2020/0326627 to Jiang et al., entitled “Organometallic Photoresist Developer Compositions and Processing Methods”, incorporated herein by reference.

It has also been discovered that solventless development, also referred to as dry development, can be employed with organotin materials. Dry development can include, for example, selective removal of the irradiated or non-irradiated regions of the photoresist by exposing the material to an appropriate plasma or appropriate flowing gas. Dry development of organotin resists has been described in PCT Publication No. 2020/132281A1 by Volosskiy et al., entitled “Dry Development of Resists”, and in published U.S. Patent Application No. 2023/0100995 to Cardineau et al., entitled “High Resolution Latent Image Processing and Thermal Development”, both of which are incorporated herein by reference. In such dry development processes, development can be achieved by exposing the irradiated substrate to a plasma or a thermal process while flowing a gas comprising a small molecule reactant (reactive gas) that facilitates removal of irradiated or non-irradiated regions. In some embodiments, the developer can be HBr or HBr plasma. In other embodiments, the reactive developer gas can be a compound QxZy or where Q is B, A1, Si, C, S, or SO with x>0 and Z is C1, H, Br, or F with y>0. In further embodiments, the reactive developer gas can be an amine, a silyl halide. an alcohol, an amide, a sulfonic acid, a carboxylic acid, a thiol, tin halide, germanium halide, and mixtures thereof. The reactive gas species can be introduced in a gaseous form or activated into a plasma state to enhance reactivity. In the Examples, the baked, patterned wafers were developed with HBr plasma in an etch reactor from Tokyo Electron Ltd. (TEL) in a negative tone development process to form developed wafers. Following development, a rinse step can be conducted using water or a positive tone developer solution if desired to further remove undesired material from the pattern, and such methods have been described in U.S. Pat. No. 11,480,874 to Kocsis et al., entitled “Patterned Organometallic Photoresists and Methods of Patterning,” incorporated herein by reference.

Solventless development can be performed at various process conditions and the process conditions can be selected to optimize the development for certain developer species and organometallic coatings. The temperature of the developer gas or etch chamber can influence the efficacy of the solventless development, as can the duration of the development, and the pressure of the etch chamber during development. In some embodiments, the solventless development can be performed at a temperature from about 10° C. to about 100° C., from about 20° C. to about 80° C., or from about 30° C. to about 60° C. In other embodiments, the solventless development can be performed at a temperature from about 100° C. to about 250° C., from about 120° C. to about 230° C., or from about 150° C. to about 200° C. In some embodiments, the solventless development process can be performed for about 10 seconds, about 20 seconds, or about 40 seconds. In other embodiments, the solventless development process can be performed for more than about 3 seconds and less than about 5 minutes, from about 10 seconds to about 2 minutes in further embodiments, and from about 20 seconds to about 60 seconds in yet further embodiments. In some embodiments, the solventless development process can be performed at reduced pressures in other embodiments the solventless development process can be performed at near atmospheric pressures, and in other embodiments the solvent development process can be performed at higher than atmospheric pressures. In other embodiments pressure can be from about 0.1 mTorr (mT) to about 800 mT, in other embodiments the pressure can be from about 1 mT to about 500 mT, and from about 10 mTorr to about 300 mT in further embodiments. In embodiments wherein the solventless development process is conducted at pressures near or above atmospheric pressure, the solventless development process can be performed at pressures from about 100 Torr to about 1000 Torr, from about 100 Torr to about 800 Torr in further embodiments, and from about 200 Torr to about 800 Torr in other embodiments. A person of ordinary skill in the art will realize that additional values of temperatures, durations, and pressures within the explicitly recited ranges above are contemplated and part of the present disclosure.

After completion of the development step including any optional rinses, the coating materials can be heat treated to further condense the material and to further dehydrate, densify, or remove residual developer from the material. This heat treatment can be particularly desirable for embodiments in which the oxide coating material is incorporated into the ultimate device, although it may be desirable to perform the heat treatment for some embodiments in which the coating material is used as a resist and ultimately removed if the stabilization of the coating material is desirable to facilitate further patterning. In particular, the baking of the patterned coating material can be performed under conditions in which the patterned coating material exhibits desired levels of etch selectivity. In some embodiments, the patterned coating material can be heated to a temperature from about 100° C. to about 600° C., in further embodiments from about 175° C. to about 500° C. and in additional embodiments from about 200° C. to about 400° C. The heating can be performed for at least about 1 minute, in other embodiment for about 2 minutes to about 1 hour, in further embodiments from about 2.5 minutes to about 25 minutes. The heating may be performed in air, vacuum, or an inert gas ambient, such as Ar or N₂. A person of ordinary skill in the art will recognize that additional ranges of temperatures and time for the heat treatment within the explicit ranges above are contemplated and are within the present disclosure. Likewise, nonthermal treatments, including blanket UV exposure, or exposure to an oxidizing plasma such as O₂ may also be employed for similar purposes.

### EXAMPLES

### Example 1. Preparation of Solutions and UV-Vis Absorbance of Films Showing Mitigation of Dodecamer Formation

This example demonstrates the formation of films from phosphonate-enhanced organotin photoresist solutions, and the shift in absorbance corresponding to the formation of lower molecular species compared to organotin films without phosphonate compounds.

Three organotin photoresist solutions were prepared from a 80/20 mol. % blend of two different monoalkyltin trialkoxides. The blended precursors were mixed in a 62/38 vol. % blend of 1-pentanol/1-propanol having an H₂O concentration adjusted to 1000 ppm to form 0.05M [Sn] solutions. An appropriate mass of tert-butylphosphonic acid or methylphosphonic acid was added to two of the solutions to form a molar ratio of 1 or of 2 phosphonate to Sn, corresponding to samples PRZ-P1 and PRZ-P2, respectively. A third solution, PRZ, without any phosphonate served as the Control.

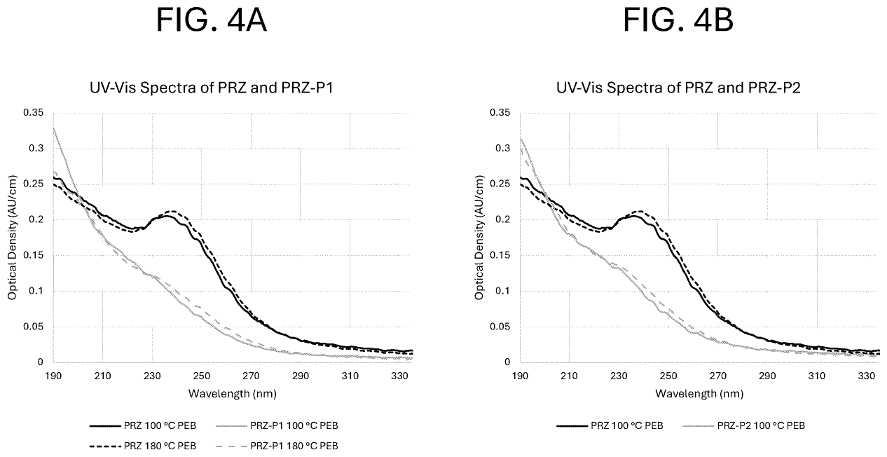

Films were prepared by spin coating each solution onto silicon wafers to form coated wafers followed by baking at 100° C. or 180° C. for 60s. Following completion of the baking step, UV-Vis spectroscopy was conducted on each film and the results are presented in FIGS. 4A and 4B, respectively.

The 1000 ppm water added to the solvent is known to promote growth of oxo-hydroxo clusters in monoalkyltin solutions. As the monoalkyltin trialkoxide precursors hydrolyze, oxo-hydroxo clusters, such as dodecamers, are generally formed. The film samples prepared from the control solution absent any phosphonate compounds exhibit a distinct increase in measured optical density around about 235 nm which is consistent with the peaks observed for dodecameric species as described by Haitjema et al. in J. Photopolym. Sci. Technol., Vol. 30, No. 1, (2017), 99-102. In comparison, the film samples prepared from PRZ-P1 and PRZ-P2 comprising the phosphonate compounds have a measured optical density consistent with the absence of dodecameric species in the films. Even for films baked at 180° C., the significant formation of dodecameric species is not observed for the phosphonate-containing samples. The presence of phosphonate compounds in the organotin photoresist solutions can mitigate the formation of dodecamers and other high nuclearity tin species in the films which can improve the homogeneity of the films and the fidelity of the patterned features.

### Example 2. Modification of Radiation-Induced Thermolysis Behavior of Organotin Films with and without Phosphonate

This example demonstrates the improvement in post-exposure thermal stability of organotin films comprising phosphonate compounds. A photoresist solution was prepared from mixing per-deuterated tert-butyltin tris (3-pentoxide) (i.e., (CD₃)₃CSn(3-pentoxide) ₃), a 62/38 mass % blend of 1-pentanol/1-propanol adjusted to have an H₂O concentration of 300 ppm, and tert-butylphosphonic acid to form a 0.052 M [Sn] solution referred to as PS1. The solution PS1 was prepared such that the molar ratio of tert-butylphosphonic acid to Sn was 0.5. A second photoresist solution PS2 was prepared in an identical manner to PS1 except that no phosphonate compound was added to the solution.

The solutions R¹ and C1 were spin coated onto Si wafers and subjected to a post-apply bake (PAB) of 100° C. for 60 seconds to give film samples according to Table 1.

TABLE 1

| Film Sample | Precursor Solution | PEB? |
|---|---|---|
| R1 | PS1 | No |
| R2 | PS1 | Yes |
| C1 | PS2 | No |
| C2 | PS2 | Yes |

The film samples were prepared having thicknesses of approximately 35 nm for films R¹ and R² and approximately 25 nm for films C1 and C2. Following the PAB, the films were exposed to EUV radiation on an ASML TwinScan NXE 3400 exposure tool to form an array of exposed pads that were each individually exposed to doses of radiation from 1 to 80 mJ/cm². Following exposure, one film prepared from PS1 and PS2 were subjected to a post-exposure bake (PEB) at 180° C. for 60s. The other two films were not baked.

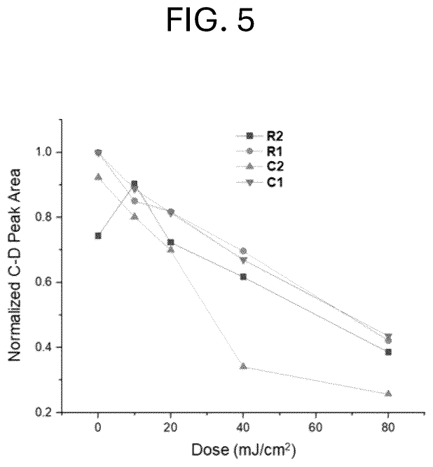

After performing the PEB, the films were analyzed via FTIR, the spectra were collected, and the areas under the peaks corresponding to C-D stretches (wavenumbers 2000 cm⁻¹ to 2300 cm⁻¹) were measured as a function of EUV dose received for each sample. The resulting plot of normalized C-D peak area vs. dose for each sample is plotted in FIG. 5. The C-D peak areas were normalized to the C-D peak areas measured for the unexposed film samples R¹ and C1.

A perdeuterated organotin precursor was used for this analysis to aid in the collection of FTIR spectra wherein differentiation between phosphonate-bound organic groups and tin-bound organic groups can be achieved. As radiation is absorbed by the organotin film and during the subsequent PEB process, Sn—C bonds are broken and the corresponding organic groups are liberated from the film to result in lower organic content in the irradiated regions. The inclusion of a phosphonate compound, such as tert-butylphosphonic acid, introduces organic groups that can absorb infrared radiation at similar wavelengths to the organic groups within non-deuterated organotin species and can make analysis of loss of tin-bound organic groups difficult. Therefore, the use of perdeuterated organotin precursors can allow for separate analysis of organic groups corresponding to the organotin species independent of the organic groups corresponding to the phosphonate compounds.

As shown in FIG. 5, the samples without any phosphonate compound show a drastic difference in slope between films receiving a PEB (Film Sample C2) and films that did not receive a PEB (Film Sample C1). Radiation absorption can lead to a decrease in C-D peak area (i.e., loss of tin-bound organic groups via Sn—C cleavage) as a function of radiation dose received. After a PEB, and as is consistent with a radiolysis-induced thermolysis process, a further decrease in C-D peak area is observed for films without phosphonate compounds. For films R¹ and R² comprising a phosphonate compound, a much smaller difference in C-D area is seen between the Film Sample R² subjected to a PEB and Film Sample R¹ that did not receive a PEB which suggests that the phosphonate compound is effective at thermally stabilizing the Sn—C bonds in the irradiated areas. In other words, the presence of the phosphonate compounds within the organotin matrix can reduce the amount of thermolysis that occurs in irradiated areas. The control over the post-irradiation thermolysis process can enable wider positive-tone process windows, higher processing temperatures, and can decrease variability due to processing.

### Example 3: Cross Sectional Profile Improvements for Organotin Photoresist Compositions with Phosphonates

This example demonstrates an improvement in cross sectional profile, specifically a reduction in T-topping of line space patterns, for organotin photoresist compositions with phosphonate additives.

A photoresist precursor solution was prepared by combining isopropyl tin tris (sec-butoxide) (iPrSn(sBuO) 3) and a solvent comprising 62% 1-pentanol and 38% 1-propanol by weight to form a solution having a final Sn concentration of 0.084 M. The precursor solution was divided into two aliquots and a unique phosphonate additive was added to each aliquot to form phosphonate enhanced compositions PRX-P1 and PRX-P2 according to Table 2. For comparison, a non-phosphonate-enhanced precursor solution PRX comprising 0.088 M iPrSn(sBuO3) in 62% 1-pentanol and 38% 1-propanol by weight was prepared. Prior to formulation, the solvent was normalized to contain water at a concentration of 300 ppm by weight.

TABLE 2

| Photoresist | | | |
|---|---|---|---|
| Precursor | | Organotin | Phosphonate |
| Solution | Solvent | Composition | Composition |
| PRX | 62% 1-pentanol | iPrSn(sBuO₃) | None |
| | (by weight) | 0.088M | |
| | 38% 1-propanol | | |
| | (by weight) | | |
| PRX-P1 | 62% 1-pentanol | iPrSn(sBuO₃) | Methyl |
| | (by weight) | 0.084M | phosphonic Acid |
| | 38% 1-propanol | | (0.1:Sn) |
| | (by weight) | | |
| PRX-P2 | 62% 1-pentanol | iPrSn(sBuO₃) | Tert-Butyl |
| | (by weight) | 0.084M | phosphonic Acid |
| | 38% 1-propanol | | (0.1:Sn) |
| | (by weight) | | |

The three photoresist precursor solutions PRX, PRX-P1, and PRX-P2 were deposited on 300 mm Si wafers with a spin-on-glass underlayer. Deposition was achieved through spin coating at a speed of about 2000 rpm to form a coating having a thickness of about 30 nm. The coated wafers were then subjected to a post application bake (PAB) for 60 seconds at a temperature of 100° C. s. The coated wafers were then patterned with different doses of 13.5 nm EUV radiation on an ASML NXE3400 exposure tool to create an array of line/space patterns having a target critical dimension (CD) of 14 nm on a 28 nm pitch (14p28). Different pads on the array were subjected to different doses corresponding to different measured values of critical dimension. The wafers were then subjected to a post-exposure bake (PEB) at 220° C. for 60s. Following the PEB, the wafers were developed with HBr plasma in a TEL etch platform at a temperature of 60° C. for either 10, 20, or 40 seconds. The developed coated wafers were then subjected to a post development heat treatment at a temperature of 200° C. for 90 seconds.

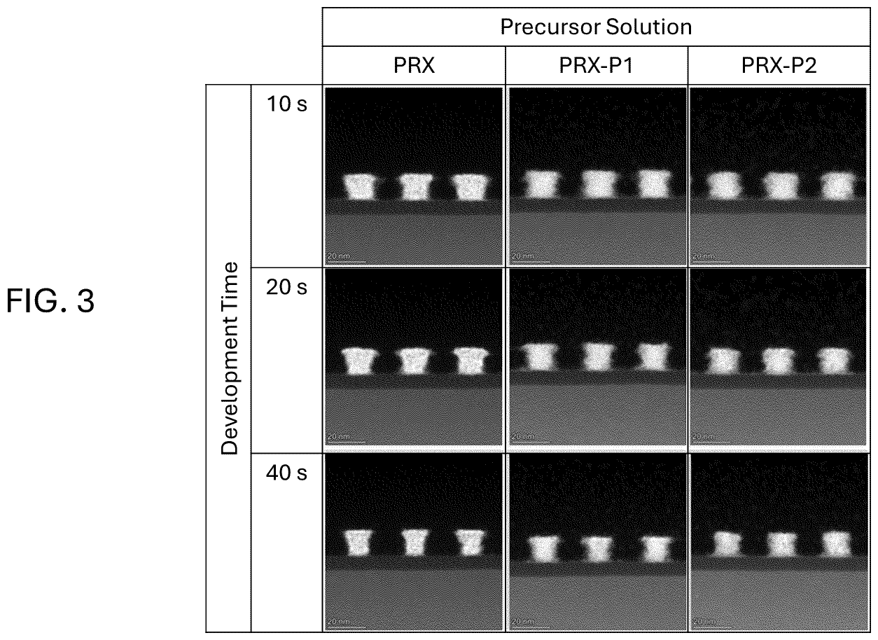

The pad having an average critical dimension closest to the target dimension of 14 nm, as determined by CD-SEM analysis, was then analyzed using cross-sectional transmission electron microscopy (XTEM). Analysis was conducted by generating cross-sectional images of the pad using a Thermo Fisher Scientific Themis Z TEM tool at an accelerating voltage of 200 kV. The XTEM images produced are presented in FIG. 3. Visual observation of the XTEM images indicates that the addition of a phosphonate compound to the photoresist precursor solution can reduce the severity of T-topped features. T-topped features can be characterized as having a top layer with a critical dimension significantly larger than the rest of the pattern. A tapered cross sectional profile wherein the critical dimension decreases along the vertical height of the feature from the top to the substrate can also accompany T-topped features. The XTEM images of PRX-P1 and PRX-2 show reductions in tapered cross sectional profile and/or a wide top layer. As determined by visual observation, tertbutylphosphonic acid was more effective in improving cross sectional profiles than methyl phosphonic acid at the same concentration relative to Sn.

### Example 4: Solution Stability Improvements for High Water Concentration Organotin Photoresist Precursor Solutions with Phosphonate Additives

A photoresist precursor solution was formulated by combining a mixture of 20% methyl tin tris (tertamoxide) (MeSn(OtAm) 3) by mole and 80% tert-butyl tin tris (3-pentoxide) (tBuSn(03-pent) 3) by mole with a solvent comprising 62% 1-pentanol and 38% 1-propanol by mass to form a solution having a Sn concentration of 0.05 M. This formulation was performed with the alcohol having 300 ppm, 1,000 ppm, and 4,000 ppm water by mass to prepare three precursor solutions with varying water concentrations. Each of the three precursor solutions was divided into three aliquots, to two of which a phosphonate additive methylphosponic acid (P1) or tertbutyl phosphonic acid (P2) was added, according to Table 3.

TABLE 3

| | | Phosphonate Additive |
|---|---|---|
| Precursor Sample | Water Concentration | (molar ratio) |
| PRZ-300 | 300 ppm | — |
| PRZ-1000 | 1000 ppm | — |
| PRZ-4000 | 4000 ppm | — |
| PRZ-P1-300 | 300 ppm | P1 (0.5:Sn) |
| PRZ-P1-1000 | 1000 ppm | P1 (0.5:Sn) |
| PRZ-P1-4000 | 4000 ppm | P1 (0.5:Sn) |
| PRZ-P2-300 | 300 ppm | P2 (0.5:Sn) |
| PRZ-P2-1000 | 1000 ppm | P2 (0.5:Sn) |
| PRZ-P2-4000 | 4000 ppm | P2 (0.5:Sn) |

The formulated precursor samples were placed in sealed containers and monitored over the course of 4 weeks for visible precipitate. The stability results for each precursor sample is shown in Table 4, wherein N indicates that no visible precipitation was observed after the 4 week duration and Y indicates that visible precipitate was observed after the 4 week duration, further detailing at what point in time the precipitation was observed.

TABLE 4

| Precursor Sample | Precipitation? |
|---|---|
| PRZ-300 | N (4 weeks) |
| PRZ-1000 | N (4 weeks) |
| PRZ-4000 | Y (3 weeks) |
| PRZ-P1-300 | Y (immediately) |
| PRZ-P1-1000 | Y (3 weeks) |
| PRZ-P1-4000 | N (4 weeks) |
| PRZ-P2-300 | N (4 weeks) |
| PRZ-P2-1000 | N (4 weeks) |
| PRZ-P2-4000 | N (4 weeks) |

Sample PRZ-P1-300 precipitated immediately following formulation. Samples PRZ-4000 and PRZ-P1-1000 precipitated about 3 weeks following formulation. The remaining samples contained no visible precipitate after the 4 week duration. The phosphonate enhanced photoresist precursor solutions having water at a concentration of 4,000 ppm were stable and free of visible precipitate for longer than the same precursor solution having no phosphonate additive. Surprisingly, samples comprising methyl phosphonic acid (P1) and water at a concentration of either 300 ppm or 1000 ppm were stable and free of visible precipitate for less time than the same precursor solution having no phosphonate additive. Mass spectrometry studies of the samples comprising additive P2 suggested that increasing water concentrations reduced the cluster sizes in solution. While not wanting to be limited by theory, the precipitate in these phosphonate enhanced solutions may not be associated with the formation of dodecameric tin species, as Example 1 indicates that a similar precursor solution can be deposited to form a film with a reduced amount of dodecameric tin species. This suggests that some phosphonate additives can form organotin phosphorous clusters that can be more stable at higher water concentrations. Additionally, the addition of phosphonate additives can enable organotin precursor solutions to maintain stability for longer periods of time at higher water concentrations, indicating the effectiveness reducing the formation of insoluble precipitates which can be influenced by the presence of water in the precursor solution.

### Further Inventive Concepts:

A1. A method for the formation of a radiation patternable coating, the method comprising:
depositing a precursor solution comprising a solvent and a precursor composition for forming a radiation sensitive film onto a surface of a substrate, wherein the precursor solution comprises a mixture of solvent, a radiation sensitive organometallic precursor composition with hydrolysable ligands, and a phosphonate;
removing the solvent to form a solid coating comprising RM moieties and phosphonate moieties within an oxo-hydroxo network, wherein R is an organic ligand and M is a metal;
irradiating the solid coating with patterned EUV radiation;
performing a post exposure bake at a temperature of at least 205° C. for at least about 40 seconds; and
after the post exposure bake, developing the solid coating to form a physical pattern.

A2. The method of inventive concept A1 wherein the phosphonate comprises a compound represented by the formula R¹PO(OR²) 2, represented by Structure 1:

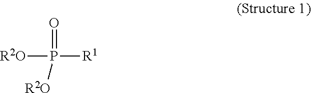

where R¹ is H or a linear, branched, cyclic, aromatic, substituted, or unsubstituted hydrocarbyl group having from 1 to 10 carbon atoms and each R² is independently chosen from H or a saturated, unsaturated, aromatic, or aliphatic hydrocarbyl group having from 1 to 10 carbon atoms.

A3. The method of inventive concept A1 wherein the phosphonate comprises aromatic groups, unsaturated alkyl groups, or heteroatoms, or a combination thereof.

A4. The method of inventive concept A1 wherein the phosphonate comprises an aromatic group with a nitro group bound to the aromatic group.

A5. The method of inventive concept A1 wherein the phosphonate comprises methylphosphonic acid, tert-butylphosphonic acid, diethoxyalyllphosphonate, allylphosphonic acid, benzylphosphonic acid, or phenylphosphonic acid or combinations thereof.

A6. The method of inventive concept A1 wherein the phosphonate comprises tert-butylphosphonic acid.

A7. The method of inventive concept A1 wherein the phosphonate is essentially free of vinyl groups, hydroxyl functional groups, heteroatom functional groups, or a combination thereof.

A8. The method of inventive concept A1 wherein the solution comprises the phosphonate in an amount from about 1 mole percent to about 250 mole percent relative to the total metal.

A9. The method of inventive concept A1 wherein the solution comprises the phosphonate in an amount from about 1 mole percent to about 75 mole percent relative to the total metal.

A10. The method of inventive concept A1 wherein the solution is essentially free of carboxylate functional groups, halogen groups, vinyl functional groups and phosphonate with C—OH groups and wherein the solution has a tin concentration from about 0.0025 M to about 1.4 M.

A11. The method of inventive concept A1 wherein the solvent comprises an alcohol, an ether, a ketone, an aromatic compound, an aliphatic hydrocarbon, or an ester, or a combination thereof.

A12. The method of inventive concept A1 wherein the solvent comprises one or more alcohol.

A13. The method of inventive concept A1 wherein the solvent comprises 1-pentanol, 1-propanol, 4-methyl-2-pentanol, or combinations thereof.

A14. The method of inventive concept A1 wherein the precursor solution has a selected amount of water from about 150 ppm to about 20,000 ppm by weight of water.

A15. The method of inventive concept A1 further comprising adjusting the solvent to have a selected amount of water.

A16. The method of inventive concept A1 wherein M is Sn.

A17. The method of inventive concept A1 wherein R is a substituted or unsubstituted organic ligand with 1 to 31 carbon atoms and an Sn—C bond.

A18. The method of inventive concept A1 wherein R comprises a cyclic alkyl group, an aromatic group, a fluorinated group, an unbranched alkyl group, a branched alkyl group, or a combination thereof.

A19. The method of inventive concept A1 wherein the radiation sensitive organometallic precursor composition comprises an organotin compound represented by the formula RSnL₃ wherein R is a substituted or unsubstituted organic ligand with 1 to 31 carbon atoms and an Sn—C bond and L is a hydrolysable ligand.

A20. The method of inventive concept 19 wherein the precursor solution further comprises an organotin compound represented by the formula R′SnL′₃ wherein R’ is a substituted or unsubstituted hydrocarbyl ligand with 1 to 31 carbon atoms and an Sn—C bond and L′ is a hydrolysable ligand, wherein R′ is different from R.

A21. The method of inventive concept A19 wherein the hydrolysable ligand is an alkoxide, a dialkylamide, an alkylacetylide, an alkylsilylamide, or a combination thereof.

A22. The method of inventive concept A1 wherein the substrate comprises a silicon wafer.

A23. The method of inventive concept A1 wherein the solid coating comprises Sn—O—P and/or Sn—O—P—O—Sn bonds within the oxo-hydroxo network.

A24. The method of inventive concept A1 wherein the solid coating has improved homogeneity with respect to a comparative solid coating prepared without phosphonate, as measured by a lower optical density from about 210 nm to about 245 nm.

A25. The method of inventive concept A1 wherein the solid coating is essentially absent dodecameric species as determined by UV-visible spectroscopy.

A26. The method of inventive concept A1 wherein the solid coating has a thickness from about 1 nm to about 50 nm.

A27. The method of inventive concept A1 wherein the patterned EUV radiation has a dose from about 1 mJ/cm² to about 150 mJ/cm².

A28. The method of inventive concept A1 wherein the post exposure bake is performed at a temperature of about 210° C. to about 275° C.

A29. The method of inventive concept A1 wherein the solid coating has improved thermal stability of organic ligands after post exposure baking with respect to a comparative solid coating prepared without phosphonate, as measured by FTIR.

A30. The method of inventive concept A1 wherein developing comprises contacting the solid coating with a developer solution composition and wherein the developer solution composition comprises an organic solvent.

A31. The method of inventive concept A1 wherein developing comprises solventless development.

A32. The method of inventive concept A31 wherein the solventless development comprises contacting the solid coating with a reactive gas or a plasma.

A33. The method of inventive concept A31 wherein the solventless development comprises contacting the solid coating with HBr plasma.

A34. The method of inventive concept A1 wherein the physical pattern comprises phosphonate moieties within an oxo-hydroxo network.

A35. The method of inventive concept A1 further comprising the step of heating the coating in a heat treatment step from a temperature of about 100° C. to about 600° C. after the development.

A36. The method of inventive concept A1 wherein the physical pattern comprises features with a substantially vertical side profile.

A37. The method of inventive concept A1 further comprising, after the depositing, heating at a temperature from about 45° C. to about 250° C.

A38. The method of any one of inventive concepts A31-A33 wherein the solventless development comprises the method for forming a pattern of any one of inventive concepts B1-B15.

A39. The method of any one of inventive concepts A1 to A38 wherein the precursor solution comprises the precursor solution of any one of claims 1 to 26.

A40. The method of any one of inventive concepts A1 to A38 wherein the precursor solution comprises the precursor solution of any one of inventive concepts C1 to C27.

A41. The method of any one of inventive concepts A1 and A23 to A38 wherein the precursor solution comprises the precursor solution of any one of inventive concepts D1 to D24.

B1. A method for forming a pattern, the method comprising: developing a virtual image formed by irradiating a layer comprising radiation sensitive RSn moieties and phosphonate moieties in a solventless developing process, wherein developing comprises preferentially removing a non-irradiated portion of the virtual image to form a negative tone pattern.

B2. The method of inventive concept B1 wherein the layer comprises an organotin oxo-hydroxo network having organo ligands R attached to Sn via radiation sensitive Sn—C bonds, wherein R comprises an alkyl group having from 1 to 31 carbons atoms, optionally substituted with one or more heteroatom functional groups and optionally comprising one or more unsaturated and/or aromatic moieties.

B3. The method of inventive concept B2 wherein the phosphonate moieties are within the oxo-hydroxo network.

B4. The method of inventive concept B2 wherein the layer comprises Sn—O—P and/or Sn—O—P—O—Sn bonds within the oxo-hydroxo network.

B5. The method of inventive concept B1 wherein the layer is essentially free of phosphonate moieties with C—OH groups, carboxylate groups or vinyl groups.

B6. The method of inventive concept B1 wherein the solventless developing comprises exposing the layer to a plasma or a flowing gas.

10 B7. The method of inventive concept B6 wherein the plasma comprises HBr plasma.

B8. The method of inventive concept B1 wherein the developing is performed in an etch reactor.

B9. The method of inventive concept B1 further comprising rinsing with a positive tone developer composition after the developing step.

B10. The method of inventive concept B1 further comprising rinsing with water after the developing step.

B11. The method of inventive concept B1 wherein the developing is performed for about 3 seconds to about 5 minutes.

B12. The method of inventive concept B1 wherein the developing is performed at a temperature from about 10° C. to about 250° C.

B13. The method of inventive concept B1 wherein the developing is performed at a pressure from about 0.1 mT to about 800 mT.

B14. The method of inventive concept B1 wherein the developing is performed at a pressure from about 100 Torr to about 1,000 Torr.

B15. The method of inventive concept B1 wherein R is a substituted or unsubstituted organic ligand with 1 to 31 carbon atoms and an Sn—C bond.

B16. The method of inventive concept B1 wherein R comprises a cyclic alkyl group, an aromatic 5 group, a fluorinated group, an unbranched alkyl group, a branched alkyl group, or a combination thereof.

B17. The method of inventive concept B1 further comprising, prior to performing the developing:
depositing a precursor solution comprising a solvent and a precursor composition, RSnL₃, for forming a radiation sensitive film onto a surface of a substrate, wherein the precursor solution comprises a mixture of solvent, and a phosphonate, wherein L are hydrolysable ligands;
removing the solvent to form a solid coating comprising RSn moieties and phosphonate moieties within an oxo-hydroxo network;
irradiating the solid coating with patterned EUV radiation;
performing a post exposure bake at a temperature of at least 205° C. for at least about 40 seconds.

B18. The method of inventive concept B17 wherein the precursor solution comprises the precursor solution of any one of claims 1 to 26.

B19. The method of inventive concept B17 wherein the precursor solution comprises the precursor solution of any one of inventive concepts C1 to C27.

B20. The method of inventive concept B17 wherein the precursor solution comprises the precursor solution of any one of inventive concepts D1 to D24.

B21. The method of inventive concept B17 wherein the solid coating has a thickness from about 1 nm to about 50 nm.

B22. The method of inventive concept B17 wherein the patterned EUV radiation has a dose from about 1 mJ/cm² to about 150 mJ/cm².

B23. The method of inventive concept B17 wherein the post exposure bake is performed at a temperature of about 210° C. to about 275° C.

B24. The method of inventive concept B17 wherein the solid coating has improved thermal stability of organic ligands after post exposure baking with respect to a comparative solid coating prepared without phosphonate, as measured by FTIR.

B25. The method of inventive concept B1 wherein the negative tone pattern comprises phosphonate moieties within an oxo-hydroxo network.

B26. The method of inventive concept B1 further comprising the step of heating the coating in a heat treatment step from a temperature of about 100° C. to about 600° C. after the development.

B27. The method of inventive concept B1 wherein the negative tone pattern comprises features with a substantially vertical side profile.

B28. The method of inventive concept B17 further comprising, after the depositing, heating at a temperature from about 45° C. to about 250° C.

C1. A precursor solution comprising a mixture of solvent, a radiation sensitive organometallic precursor composition with hydrolysable ligands, and a phosphonate, having a tin concentration from about 0.005 M to about 1.4 M and a selected amount of water from about 150 ppm to about 5000 ppm, wherein the precursor solution has reduced dodecamer formation as measured by a lower optical density from about 210 nm to about 245 nm.

C2. The precursor solution of inventive concept C1 wherein the solution is essentially free of carboxylate functional groups, halogen groups, vinyl functional groups and phosphonate with C-OH groups.

C3. The precursor solution of inventive concept C1 wherein the phosphonate comprises a compound represented by the formula R¹PO(OR²) 2, represented by Structure 1:

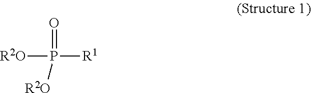

where R¹ is H or a linear, branched, cyclic, aromatic, substituted, or unsubstituted hydrocarbyl group having from 1 to 10 carbon atoms and each R² is independently chosen from H or a saturated, unsaturated, aromatic, or aliphatic hydrocarbyl group having from 1 to 10 carbon atoms.

C4. The precursor solution of inventive concept C1 wherein the phosphonate comprises aromatic groups, non-halogen heteroatoms, or a combination thereof.

C5. The precursor solution of inventive concept C1 wherein the phosphonate comprises an aromatic group with a nitro group bound to the aromatic group.

C6. The precursor solution of inventive concept C1 wherein the phosphonate comprises methylphosphonic acid, tert-butylphosphonic acid, diethoxyalyllphosphonate, benzylphosphonic acid, or phenylphosphonic acid or combinations thereof.

C7. The precursor solution of inventive concept C1 wherein the phosphonate comprises tert-butylphosphonic acid.

C8. The precursor solution of inventive concept C1 wherein the phosphonate is essentially free of heteroatom functional groups.

C9. The precursor solution of inventive concept C1 wherein the phosphonate is dissolved in the solution.

C10. The precursor solution of inventive concept C1 wherein the phosphonate is a first phosphonate compound and wherein the precursor solution comprises a mixture with a second phosphonate compound.

C11. The precursor solution of inventive concept C1 wherein the mixture comprises the phosphonate in an amount from about 1 mole percent to about 250 mole percent relative to the total metal.

C12. The precursor solution of inventive concept C1 where in the mixture comprises the phosphonate in an amount from about 1 mole percent to about 75 mole percent relative to the total metal.

C13. The precursor solution of inventive concept C1 wherein the solvent comprises an alcohol, an ether, a ketone, an aromatic compound, an aliphatic hydrocarbon, an ester, or a combination thereof.

C14. The precursor solution of inventive concept C1 wherein the solvent comprises one or more alcohols.

C15. The precursor solution of inventive concept C1 wherein the solvent comprises 1-pentanol, 1-propanol, 4-methyl-2-pentanol, or combinations thereof.

C16. The precursor solution of inventive concept C1 having a selected amount of water.

C17. The precursor solution of inventive concept C16 wherein the solvent has been adjusted to have the selected amount of water.

C18. The precursor solution of inventive concept C1 having a selected amount of water from about 150 ppm to about 20,000 ppm by weight of water.

C19. The precursor solution of inventive concept C1 wherein the radiation sensitive organometallic precursor composition comprises an organotin compound represented by the formula RSnL₃ wherein R is a substituted or unsubstituted organic ligand with 1 to 31 carbon atoms and an Sn—C bond and L is a hydrolysable ligand.

C20. The precursor solution of inventive concept C19 wherein R comprises a cyclic alkyl group, an aromatic group, a fluorinated group, an unbranched alkyl group, a branched alkyl group, or a combination thereof.

C21. The precursor solution of inventive concept C19 wherein R comprises a t-butyl group, an iso-propyl group, a methyl group, or a combination thereof.

C22. The precursor solution of inventive concept C19 wherein R comprises an organic ligand substituted with heteroatoms.

C23. The precursor solution of inventive concept C19 wherein the Sn—C bond is radiation sensitive.

C24. The precursor solution of inventive concept C19 further comprising an organotin compound represented by the formula R′SnL′₃ wherein R′ is a substituted or unsubstituted hydrocarbyl ligand with 1 to 31 carbon atoms and an Sn—C bond and L′ is a hydrolysable ligand, wherein R′ is different from R.

C25. The precursor solution of inventive concept C1 wherein the hydrolysable ligand is an alkoxide, a dialkylamide, an alkylacetylide, an alkylsilylamide, or a combination thereof.

C26. The precursor solution of inventive concept C1 wherein the hydrolysable ligand is tert-butoxide, sec-butoxide, pentan-3-yloxide, tert-amyloxide, or a combination thereof.

C27. The precursor solution of inventive concept C1 further comprising an inorganic hydrolytically sensitive metal compound represented by the formula MLₙ, wherein M is a Group 2-Group 16 metal, and 2<n<6, and L is a hydrolysable ligand, wherein MLₙ is at a concentration from about 0.025 mole % to about 50 mole % of the total metal.

D1. A precursor solution comprising a mixture of solvent, a radiation sensitive organometallic precursor composition with hydrolysable ligands, and a phosphonate, having a metal concentration from about 0.005 M to about 1.4 M, wherein the phosphonate comprises a diester compound represented by the formula R¹PO(OR²) 2, represented by Structure 1:

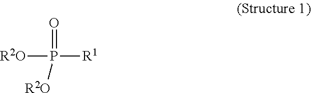

where R¹ is H or a linear, branched, cyclic, aromatic, substituted, or unsubstituted hydrocarbyl group having from 1 to 10 carbon atoms and each R² is independently chosen from a saturated, unsaturated, aromatic, or aliphatic hydrocarbyl group having from 1 to 10 carbon atoms.

D2. The precursor solution of inventive concept D1 wherein the phosphonate comprises aromatic groups, non-halogen heteroatoms, or a combination thereof.

D3. The precursor solution of inventive concept D1 wherein the phosphonate comprises an aromatic group with a nitro group bound to the aromatic group.

D4. The precursor solution of inventive concept D1 wherein the phosphonate comprises diethoxyalyllphosphonate.

D5. The precursor solution of inventive concept D1 wherein the phosphonate is essentially free of heteroatom functional groups.

D6. The precursor solution of inventive concept D1 wherein the phosphonate is dissolved in the solution.

D7. The precursor solution of inventive concept D1 wherein the phosphonate is a first phosphonate compound and wherein the precursor solution comprises a mixture with a second phosphonate compound.

D8. The precursor solution of inventive concept D1 wherein the mixture comprises the phosphonate in an amount from about 1 mole percent to about 250 mole percent relative to the total metal.

D9. The precursor solution of inventive concept D1 where in the mixture comprises the phosphonate in an amount from about 1 mole percent to about 75 mole percent relative to the total metal.

D10. The precursor solution of inventive concept D1 wherein the solvent comprises an alcohol, an ether, a ketone, an aromatic compound, an aliphatic hydrocarbon, an ester, or a combination thereof.

D11. The precursor solution of inventive concept D1 wherein the solvent comprises one or more alcohols.

D12. The precursor solution of inventive concept D1 wherein the solvent comprises 1-pentanol, 1-propanol, 4-methyl-2-pentanol, or combinations thereof.

D13. The precursor solution of inventive concept D1 having a selected amount of water.

D14. The precursor solution of inventive concept D13 wherein the solvent has been adjusted to have the selected amount of water.

D15. The precursor solution of inventive concept D1 having a selected amount of water from about 150 ppm to about 20,000 ppm by weight of water.

D16. The precursor solution of inventive concept D1 wherein the radiation sensitive organometallic precursor composition comprises an organotin compound represented by the formula RSnL₃ wherein R is a substituted or unsubstituted organic ligand with 1 to 31 carbon atoms and an Sn—C bond and L is a hydrolysable ligand.

D17. The precursor solution of inventive concept D16 wherein R comprises a cyclic alkyl group, an aromatic group, a fluorinated group, an unbranched alkyl group, a branched alkyl group, or a combination thereof.

D18. The precursor solution of inventive concept D16 wherein R comprises a t-butyl group, an iso-propyl group, a methyl group, or a combination thereof.

D19. The precursor solution of inventive concept D16 wherein R comprises an organic ligand substituted with heteroatoms.

D20. The precursor solution of inventive concept D16 wherein the Sn—C bond is radiation sensitive.

D21. The precursor solution of inventive concept D16 further comprising an organotin compound represented by the formula R′SnL′₃ wherein R′ is a substituted or unsubstituted hydrocarbyl ligand with 1 to 31 carbon atoms and an Sn—C bond and L′ is a hydrolysable ligand, wherein R′ is different from R.

D22. The precursor solution of inventive concept D1 wherein the hydrolysable ligand is an alkoxide, a dialkylamide, an alkylacetylide, an alkylsilylamide, or a combination thereof.

D23. The precursor solution of inventive concept D1 wherein the hydrolysable ligand is tert-butoxide, sec-butoxide, pentan-3-yloxide, tert-amyloxide, or a combination thereof. D24. The precursor solution of inventive concept D1 further comprising an inorganic hydrolytically sensitive metal compound represented by the formula MLₙ, wherein M is a Group 2-Group 16 metal, and 2≤n≤6, and L is a hydrolysable ligand, wherein MLₙ is at a concentration from about 0.025 mole % to about 50 mole % of the total metal.

The embodiments above are intended to be illustrative and not limiting. Additional embodiments are within the claims. In addition, although the present invention has been described with reference to particular embodiments, those skilled in the art will recognize that changes can be made in form and detail without departing from the spirit and scope of the invention. Any incorporation by reference of documents above is limited such that no subject matter is incorporated that is contrary to the explicit disclosure herein. To the extent that specific structures, compositions and/or processes are described herein with components, elements, ingredients or other partitions, it is to be understand that the disclosure herein covers the specific embodiments, embodiments comprising the specific components, elements, ingredients, other partitions or combinations thereof as well as embodiments consisting essentially of such specific components, ingredients or other partitions or combinations thereof that can include additional features that do not change the fundamental nature of the subject matter, as suggested in the discussion, unless otherwise specifically indicated. The use of the term “about” herein refers to expected uncertainties in the associated values as would be understood in the particular context by a person of ordinary skill in the art. A person of ordinary skill in the art is notified that the assertions above regarding the contemplation of subranges within explicit ranges are sincerely intended to provide explicit written description for the subranges, as clearly suggested, even though not explicitly written and that the subranges are not believed to change the character of the associated invention, although of course the specific values of parameters will certainly quantitatively change corresponding results obtained, which could influence patentability even though the basic character of the invention may not be changing, in view of the potential nature of the state of the art known or unknown at filing given that the inventiveness may follow from the factual details. A person of ordinary skill in the art is further notified that upper and lower values of explicit ranges and values within explicit ranges are intended to provide explicit written description for endpoints of subranges, furthermore explicit disclosure of upper and/and lower values of explicit ranges of a certain feature are intended to be disclosed as upper and/or lower values for additional ranges. including subranges.

What is claimed is:

1. A precursor solution comprising a mixture of solvent, a radiation sensitive organometallic precursor composition with hydrolysable ligands, and a phosphonate, having a metal concentration from about 0.005 M to about 1.4 M, wherein the solution is essentially free of carboxylate functional groups, halogen groups, vinyl functional groups and phosphonate with C—OH groups.

2. The precursor solution of claim 1 wherein the phosphonate comprises a compound represented by the formula R¹PO(OR²)₂, represented by Structure 1: 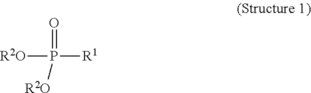
where R¹ is H or a linear, branched, cyclic, aromatic, substituted, or unsubstituted hydrocarbyl group having from 1 to 10 carbon atoms and each R² is independently chosen from H or a saturated, unsaturated, aromatic, or aliphatic hydrocarbyl group having from 1 to 10 carbon atoms.

3. The precursor solution of claim 1 wherein the phosphonate comprises aromatic groups, non-halogen heteroatoms, or a combination thereof.

4. The precursor solution of claim 1 wherein the phosphonate comprises an aromatic group with a nitro group bound to the aromatic group.

5. The precursor solution of claim 1 wherein the phosphonate comprises methylphosphonic acid, tert-butylphosphonic acid, diethoxyallylphosphonate, benzylphosphonic acid, or phenylphosphonic acid or combinations thereof.

6. The precursor solution of claim 1 wherein the phosphonate comprises tert-butylphosphonic acid.

7. The precursor solution of claim 1 wherein the phosphonate is essentially free of heteroatom functional groups.

8. The precursor solution of claim 1 wherein the phosphonate is dissolved in the solution.

9. The precursor solution of claim 1 wherein the phosphonate is a first phosphonate compound and wherein the precursor solution comprises a mixture with a second phosphonate compound.

10. The precursor solution of claim 1 wherein the mixture comprises the phosphonate in an amount from about 1 mole percent to about 250 mole percent relative to the total metal.

11. The precursor solution of claim 1 where in the mixture comprises the phosphonate in an amount from about 1 mole percent to about 75 mole percent relative to the total metal.

12. The precursor solution of claim 1 wherein the solvent comprises an alcohol, an ether, a ketone, an aromatic compound, an aliphatic hydrocarbon, an ester, or a combination thereof.

13. The precursor solution of claim 1 wherein the solvent comprises one or more alcohols.

14. The precursor solution of claim 1 wherein the solvent comprises 1-pentanol, 1-propanol, 4-methyl-2-pentanol, or combinations thereof.

15. The precursor solution of claim 1 having a selected amount of water.

16. The precursor solution of claim 15 wherein the solvent has been adjusted to have the selected amount of water.

17. The precursor solution of claim 1 having a selected amount of water from about 150 ppm to about 20,000 ppm by weight of water.

18. The precursor solution of claim 1 wherein the radiation sensitive organometallic precursor composition comprises an organotin compound represented by the formula RSnL₃ wherein R is a substituted or unsubstituted organic ligand with 1 to 31 carbon atoms and an Sn—C bond and L is a hydrolysable ligand.

19. The precursor solution of claim 18 wherein R comprises a cyclic alkyl group, an aromatic group, a fluorinated group, an unbranched alkyl group, a branched alkyl group, or a combination thereof.

20. The precursor solution of claim 18 wherein R comprises a t-butyl group, an iso-propyl group, a methyl group, or a combination thereof.

21. The precursor solution of claim 18 wherein R comprises an organic ligand substituted with heteroatoms.

22. The precursor solution of claim 18 wherein the Sn—C bond is radiation sensitive.

23. The precursor solution of claim 18 further comprising an organotin compound represented by the formula R′SnL′₃ wherein R′ is a substituted or unsubstituted hydrocarbyl ligand with 1 to 31 carbon atoms and an Sn—C bond and L′ is a hydrolysable ligand, wherein R′ is different from R.

24. The precursor solution of claim 1 wherein the hydrolysable ligand is an alkoxide, a dialkylamide, an alkylacetylide, an alkylsilylamide, or a combination thereof.

25. The precursor solution of claim 1 wherein the hydrolysable ligand is tert-butoxide, sec-butoxide, pentan-3-yloxide, tert-amyloxide, or a combination thereof.

26. The precursor solution of claim 1 further comprising an inorganic hydrolytically sensitive metal compound represented by the formula MLₙ, wherein M is a Group 2-Group 16 metal, and 2≤n≤6, and L is a hydrolysable ligand, wherein ML, is at a concentration from about 0.025 mole to about 50 mole % of the total metal.
